(19) United States
(12) Patent Application Publication
(10) Pub. No.: US 2005/0183769 A1
(43) Pub. Date: Aug. 25, 2005

(54) Method of producing substrate for dye-sensitized solar cell and dye-sensitized solar cell

(76) Inventors: Hiroki Nakagawa, Tokyo-to (JP); Yosuke Yabuuchi, Tokyo-to (JP); Hiroyuki Kobori, Tokyo-to (JP)

Correspondence Address: LADAS & PARRY LLP, 224 SOUTH MICHIGAN AVENUE, SUITE 1600, CHICAGO, IL, 60604, US

(21) Appl. No.: 10/984,700

(22) Filed: Nov. 9, 2004

(30) Foreign Application Priority Data
Nov. 10, 2003 (JP) 2003-379714

(51) Int. Cl. H01L 31/00

(52) U.S. Cl. 136/263; 438/85

(57) ABSTRACT

The main object of the invention is to provide a method capable of producing a substrate for a dye-sensitized solar cell in high yield and a method of producing a dye-sensitized solar cell with such a substrate. In order to achieve the object, there is provided, according to the invention, a method of producing a substrate for a dye-sensitized solar cell, comprising the processes of: applying, to a heat-resistant substrate, an intermediate layer-forming coating material that contains an organic material and fine particles of a metal oxide semiconductor and setting the coating to form an intermediate layer-forming layer; applying, to the intermediate layer-forming layer, an oxide semiconductor layer-forming coating material whose solids have a higher concentration of fine particles of a metal oxide semiconductor than that of those in the solids of the intermediate layer-forming coating material and setting the coating to form an oxide semiconductor layer-forming layer; sintering the intermediate layer-forming layer and the oxide semiconductor layer-forming layer to form a porous intermediate membrane and a porous oxide semiconductor membrane; and forming a first electrode layer and a substrate on the oxide semiconductor membrane.

### BACKGROUND OF THE INVENTION

1. Field of the Invention

The invention relates to a method of producing a substrate for a dye-sensitized solar cell (a dye-sensitized solar cell substrate) which allows high-yield production of a dye-sensitized solar cell, a dye-sensitized solar cell substrate produced by such a method, a method of producing a dye-sensitized solar cell with such a dye-sensitized solar cell substrate, and a dye-sensitized solar cell produced by such a method.

2. Description of the Related Art

In recent years, global warming caused by carbon dioxide has become a worldwide problem, and thus solar cells, which use solar energy, have received attention as a clean eco-friendly energy source, and active research and development has been conducted on them. While some solar cells such as single-crystal silicon solar cells, polycrystalline silicon solar cells, and amorphous silicon solar cells are already commercially available, dye-sensitized solar cells have received attention as a potential low-environmental-load and low-cost solar cell, and research and development has been performed on them.

For example, a dye-sensitized solar cell comprises a transparent substrate, a transparent electrode formed on the transparent substrate, an oxide semiconductor layer on which a dye sensitizer is fixed, an electrolyte layer containing an electrolyte, and a counter electrode substrate, which are layered in this order from the light-receiving side, and the cell is formed.

Dye-sensitized solar cells, particularly Gratzel cells, are characterized by having a porous oxide semiconductor layer which is formed by sintering titanium oxide nanoparticles. The porous oxide semiconductor layer can adsorb more dye sensitizer and provide improved light absorption performance.

In such dye-sensitized solar cells, for example, a glass substrate is used as the transparent substrate. In such a case, sintering can be performed at a temperature of 400 to 600° C. in order to form the porous membrane. When a film substrate, which is less resistant to heat than the glass substrate, is used, however, sintering must be performed at a temperature lower than the heatproof temperature of the film, and thus bonding strength between fine particles of the metal oxide semiconductor can be insufficient, so that a transfer route through which electrons produced by photoexcitation can be transferred from the dye sensitizer to the oxide semiconductor layer and the transparent electrode would insufficiently be established. In such a case, adhesion between the film substrate and the oxide semiconductor layer can also be insufficient, so that the layer cannot be as flexible as the film and thus can disadvantageously be peeled or cracked.

For example, Japanese Patent Application Laid-Open (JP-A) No. 2002-184475 discloses a method of producing a semiconductor electrode, which includes forming a layer containing an oxide semiconductor and/or its precursor on a heat-resistant substrate, heating and sintering the layer to form an oxide semiconductor membrane and transferring the oxide semiconductor membrane onto another substrate.

In such a method, the layer that contains the oxide semiconductor and/or its precursor and formed on the heat-resistant substrate is used as a transfer member. In the process of forming the transfer member, heating and sintering can be performed in a high temperature range because of the use of the heat-resistant substrate, and thus an oxide semiconductor membrane having sufficiently bonded fine particles of the metal oxide semiconductor can be formed. The substrate for receiving the transfer is not subject to heating or sintering in such a high temperature range, because the transfer member has already undergone heating and sintering in the process of forming the oxide semiconductor membrane. Thus, the substrate for receiving the transfer may comprise a film substrate (somewhat less resistant to heat) as a support member for keeping the shape of the substrate constant.

In the process disclosed in JP-A No. 2002-184475, however, adhesion between the oxide semiconductor membrane and the heat-resistant substrate can be poor after the heating and sintering, and thus it can be difficult to perform high-precision transfer of the oxide semiconductor membrane from the transfer member to another substrate. Thus, there has been a demand for an improvement in yield, prevention of poor transfer and the like.

For example, a film or plate product of a transparent resin or glass is used as a substrate for the dye-sensitized solar cell substrate, and the collecting electrode is typically made of an electrically-conductive transparent inorganic material such as indium tin oxide (ITO) and fluorine-doped tin oxide. The porous oxide semiconductor is layered by high-temperature sintering in the case where the substrate has high heat resistance (for example, see JP-A No. 2002-280587), layered on a collecting electrode by a coating method in the case where the substrate has poor heat resistance (for example, see JP-A No. 2002-280587), or layered together with a collecting electrode by a transfer method (for example, see JP-A No. 2002-184475).

If any general purpose transparent resin film can be used as the substrate, dye-sensitized solar cells with high flexibility could easily be produced at low cost, and thus dye-sensitized solar cells with a high degree of flexibility in choice of installation location and with high installation workability (even in the case of large area solar cells) could easily be produced at low cost. In addition, dye-sensitized solar cells that can easily maintain the portability (lightweight) of portable electronic devices could easily be supplied as a low cost power source or low cost auxiliary power source for portable electronic devices.

However, such a general purpose transparent resin film is relatively poor in heat resistance. If the general purpose transparent resin film is used as the substrate, therefore, the coating method or the transfer method as disclosed in JP-A No. 2002-184475 or 2002-280587 must be used to form the oxide semiconductor layer. The problems as described below, however, can be caused by such published methods in the process of forming the oxide semiconductor layer.

When the oxide semiconductor layer is formed by the coating method on a collecting electrode which has been formed on the transparent resin film, adhesion between the collecting electrode and the oxide semiconductor layer can be relatively poor because of a monolayer structure of the collecting electrode of the transparent inorganic material. Consequently, when the resulting dye-sensitized solar cell is deformed, the oxide semiconductor layer cannot follow the deformation and can easily suffer local peeling or cracking. Thus, it would be difficult to obtain dye-sensitized solar cells with both high flexibility and high performance.

In the transfer method of forming the oxide semiconductor layer together with the collecting electrode on a transparent resin film, the plan-view size of the collecting electrode in the transfer member should necessarily be not larger than that of the oxide semiconductor layer, and therefore, after the transfer process, the oxide semiconductor layer must be partially removed for the formation of a lead electrode. Since the oxide semiconductor layer is thin, the partial removal would require high processing accuracy, or the collecting electrode can easily be damaged, and thus it would be difficult to obtain high-performance dye-sensitized solar cells.

JP-A No. 2002-184475 also discloses a transfer member that is formed by a process including the steps of previously placing a metal mesh for serving as a collecting electrode on a heat-resistant substrate, applying an oxide semiconductor layer (membrane)-forming coating material to the metal mesh and sintering the coating to form an oxide semiconductor layer (see paragraph 0014). However, the problem as described below can be caused when such a transfer member is used.

In the dye-sensitized solar cell having the oxide semiconductor layer transferred from the above transfer member, a lead electrode can easily be formed, but the metal mesh part (metal layer) cannot contribute to electricity generation, and the efficiency of collection of the charge from the oxide semiconductor can be reduced at the center of the lattice of the mesh. Thus, it would be difficult to obtain high-performance dye-sensitized solar cells.

JP-A No. 2002-184475 also discloses that a releasing layer of a fluororesin or a heat-decomposable resin layer that can be burned and decomposed by sintering is previously formed on the heat-resistant substrate when a transfer member with improved transferability (peelability) of the oxide semiconductor layer (membrane) is produced (see paragraph 0011). However, the problem as described below can be caused when such a transfer member technique is used.

Since the heat-resistant temperature of the releasing fluororesin layer is relatively low (about 300° C. or lower), the sintering temperature for the formation of the oxide semiconductor layer (membrane) is not high so that it can be difficult to produce a high-electrical-performance porous oxide semiconductor membrane. In the case that the heat-decomposable resin layer that can be burned and decomposed by sintering is previously formed on the heat-resistant substrate, an oxide semiconductor layer (membrane) formed by sintering can flake off from the heat-resistant substrate immediately after the sintering, so that it can be difficult to transfer the large oxide semiconductor layer to the transfer-receiving member.

### SUMMARY OF THE INVENTION

The invention has been made in light of the above problems, and an object of the invention is to provide a method capable of producing a substrate for a dye-sensitized solar cell in high yield, a method of producing a dye-sensitized solar cell with such a substrate, and an electrically-conductive substrate that has an oxide semiconductor layer and easily allows production of high-flexibility and high-performance dye-sensitized solar cells.

In order to achieve the object, there is provided, according to the invention, a method of producing a substrate for a dye-sensitized solar cell, comprising the processes of: applying, to a heat-resistant substrate, an intermediate layer-forming coating material that contains an organic material and fine particles of a metal oxide semiconductor and setting the coating to form an intermediate layer-forming layer (the process of forming an intermediate layer-forming layer); applying, to the intermediate layer-forming layer, an oxide semiconductor layer-forming coating material whose solids have a higher concentration of fine particles of a metal oxide semiconductor than the concentration of the fine particles of the metal oxide semiconductor in the solids of the intermediate layer-forming coating material and setting the coating to form an oxide semiconductor layer-forming layer (the process of forming an oxide semiconductor layer-forming layer); sintering the intermediate layer-forming layer and the oxide semiconductor layer-forming layer to form a porous intermediate membrane and an oxide semiconductor membrane (the sintering process); and forming a first electrode layer and a substrate on the oxide semiconductor membrane (the electrode and substrate forming process).

In the invention, the oxide semiconductor layer-forming layer is formed via the intermediate layer-forming layer containing fine particles of metal oxide semiconductor so that the oxide semiconductor membrane can be formed with adequate adhesion onto the heat-resistant substrate. Conventionally, an oxide semiconductor membrane is formed on a heat-resistant substrate via an organic material membrane with no fine particles of metal oxide semiconductor. In the conventional case, cracking can easily occur after the sintering process between the organic membrane and the oxide semiconductor membrane because of a difference in thermal expansion coefficient between the organic material in the organic membrane and the fine particles of the metal oxide semiconductor in the oxide semiconductor membrane, and thus it would be difficult to form a well adhering oxide semiconductor membrane on the heat-resistant substrate. In the invention, however, an oxide semiconductor layer-forming layer is formed via an intermediate layer-forming layer containing not only an organic material but also fine particles of metal oxide semiconductor, and therefore, the above problem can hardly occur after the sintering process, and a well adhering oxide semiconductor membrane can be formed on the heat-resistant substrate. If the oxide semiconductor membrane is formed directly on the heat-resistant substrate with no intermediate membrane, their adhesion is very strong so that it can be difficult to peel off the heat-resistant substrate from the strongly adhering oxide semiconductor membrane in the process of placing the oxide semiconductor membrane onto another substrate from the heat-resistant substrate, and thus the oxide semiconductor membrane cannot be placed in a good manner on the substrate. In the invention, however, the oxide semiconductor layer-forming layer is formed via the intermediate layer-forming layer containing fine particles of metal oxide semiconductor, so that an intermediate membrane and an oxide semiconductor membrane can be placed with high accuracy on a substrate because the membranes have not only adequate adhesion to the heat-resistant substrate but also good peelability. Thus, the dye-sensitized solar cell substrate can be produced in high yield.

In the invention, the electrode and substrate forming process preferably includes: the process of a solution treatment in which a first electrode undercoat layer-forming coating material containing a dissolved metal salt or metal complex with a metal element for forming the first electrode layer is brought into contact with the oxide semiconductor membrane so that a first electrode undercoat layer is formed in the interior of or on the surface of the oxide semiconductor membrane; and the process of forming a first electrode upper layer on the first electrode undercoat layer. The first electrode undercoat layer-forming coating material can be infiltrated into the porous oxide semiconductor membrane so that a first electrode undercoat layer can be formed in the interior of the oxide semiconductor membrane. In the process of forming the first electrode upper layer, a dense first electrode layer can be produced by forming the first electrode upper layer on the first electrode undercoat layer.

In the invention, the process of forming the first electrode upper layer preferably includes: heating the first electrode undercoat layer to a temperature equal to or higher than a metal oxide film-forming temperature; and bringing the heated first electrode undercoat layer into contact with a first electrode upper layer-forming coating material containing a dissolved metal salt or metal complex with a metal element for forming the first electrode layer to form the first electrode upper layer on the first electrode under coat layer. When the first electrode upper layer is formed on the first electrode undercoat layer by this method, a dense first electrode layer can be formed on the porous oxide semiconductor membrane.

In the invention, the electrode and substrate forming process preferably includes: heating the oxide semiconductor membrane to a temperature equal to or higher than a metal oxide film-forming temperature; and bringing the heated oxide semiconductor membrane into contact with a first electrode layer-forming coating material containing a dissolved metal salt or metal complex with a metal element for forming the first electrode layer to form the first electrode layer on the oxide semiconductor membrane. In this method, the first electrode layer can be formed on the porous oxide semiconductor membrane by a simple process.

In the invention, the electrode and substrate forming process preferably includes: providing the substrate, in which the substrate comprises a transparent resin film, an electrically-conductive transparent inorganic layer formed on the resin film, and an electrically-conductive transparent organic-inorganic composite layer formed on the inorganic layer; and bonding the electrically-conductive transparent organic-inorganic composite layer to the first electrode layer. Any lead electrode can easily be connected using the electrically-conductive transparent inorganic layer. For example, even when the transfer method is used to form the oxide semiconductor layer together with the first electrode layer, the oxide semiconductor layer does not have to be partially removed for the formation of the lead electrode after the transfer process.

According to the invention, there is also provided a method of producing a dye-sensitized solar cell, comprising the processes of: forming a dye-sensitized solar cell substrate by using the above method of producing a substrate for a dye-sensitized solar cell; placing a second electrode layer and a counter substrate opposite to the first electrode layer and the substrate of the dye-sensitized solar cell substrate (the counter electrode and substrate forming process); and forming an electrolyte layer between the second electrode layer and a photoelectric conversion layer comprising at least an intermediate layer and an oxide semiconductor layer which comprise the porous intermediate membrane, the porous oxide semiconductor membrane and a dye sensitizer fixed on the surface of fine semiconductor particles of the porous intermediate membrane and the porous oxide semiconductor membrane.

As mentioned above, the dye-sensitized solar cell substrate can be produced in high yield by the above method of the invention. Thus, the dye-sensitized solar cell can be produced advantageously in terms of quality and cost by using the dye-sensitized solar cell substrate and by forming the electrolyte layer, the second electrode layer, the counter substrate and the like.

According to the invention, there is also provided a substrate for a dye-sensitized solar cell, comprising: a substrate; a first electrode layer formed on the substrate; and an oxide semiconductor layer formed on the first electrode layer, in which a metal element used as a component of the first electrode layer is detected in the oxide semiconductor layer, and the concentration of the metal element in the oxide semiconductor layer decreases in the direction from first electrode layer-side surface to opposite surface.

According to the invention, the metal element used as a component of the first electrode layer is detected in the corresponding region as stated above, so that the dye-sensitized solar cell can advantageously have a higher current-collecting efficiency.

According to the invention, there is also provided a dye-sensitized solar cell, comprising: a dye-sensitized solar cell substrate which comprises a substrate, a first electrode layer formed on the substrate, and an oxide semiconductor layer formed on the first electrode layer; a counter electrode substrate which comprises a counter substrate and a second electrode layer formed on the counter substrate, in which the second electrode layer is placed opposite to the oxide semiconductor layer; and an electrolyte layer placed between the oxide semiconductor layer and the second electrode layer, in which a metal element used as a component of the first electrode layer is detected in the oxide semiconductor layer, and the concentration of the metal element in the oxide semiconductor layer decreases in the direction from first electrode layer-side surface to opposite surface.

According to the invention, the metal element used as a component of the first electrode layer is detected in the corresponding region as stated above, so that the dye-sensitized solar cell can have a higher current-collecting efficiency.

According to the invention, there is also provided an electrically-conductive substrate, comprising: a transparent resin film; and an electrically-conductive transparent inorganic layer, an electrically-conductive transparent organic-inorganic composite layer, a first electrode layer, and an oxide semiconductor layer stacked on the transparent resin film in this order.

The electrically-conductive substrate of the invention can be used as a component member of the dye-sensitized solar cell substrate. In the electrically-conductive substrate, the oxide semiconductor layer is formed on the electrically-conductive transparent inorganic layer via the electrically-conductive transparent organic-inorganic composite layer and the first electrode layer. According to such a structure, an electrically-conductive substrate having an oxide semiconductor layer can easily be produced in which the response (adhesion) of the oxide semiconductor layer to deformation is higher than that of an oxide semiconductor layer formed directly on the electrically-conductive transparent inorganic layer by the coating method.

The plan-view size of the electrically-conductive transparent inorganic layer can be made larger than that of the oxide semiconductor layer, so that a lead electrode can easily be connected to the electrically-conductive transparent inorganic layer. Thus, even when the transfer method is used to form the oxide semiconductor layer together with the first electrode layer, the oxide semiconductor layer does not have to be partially removed for the formation of the lead electrode after the transfer process. If the present electrically-conductive substrate is used to form the dye-sensitized solar cell substrate, therefore, high processing accuracy would not be required and the risk of damage to the collecting electrode would be avoided in the process of forming the lead electrode. If the transfer member for use in forming a semiconductor layer as stated below is used, first electrodes and oxide semiconductor layers of various sizes from small to large can easily be formed on the transfer-receiving member by the transfer method.

For these reasons, dye-sensitized solar cells with both high flexibility and high performance can easily be produced using the electrically-conductive substrate of the invention.

According to the invention, there is also provided an electrode substrate for a dye-sensitized solar cell, comprising: the electrically-conductive substrate; and a sensitizing dye fixed on the oxide semiconductor layer of the electrically-conductive electrode substrate.

High-performance dye-sensitized solar cells can easily be produced using this dye-sensitized solar cell electrode substrate comprising the electrically-conductive substrate of the invention.

According to the invention, there is also provided a dye-sensitized solar cell, comprising; a dye-sensitized solar cell substrate having an oxide semiconductor layer on which a sensitizing dye is fixed; a counter electrode substrate placed opposite to the dye-sensitized solar cell substrate; and an electrolyte layer placed between the dye-sensitized solar cell substrate and the counter electrode substrate, in which the dye-sensitized solar cell substrate is the above-stated dye-sensitized solar cell substrate.

High-performance dye-sensitized solar cells can easily be produced according to this dye-sensitized solar cell structure comprising the electrically-conductive substrate of the invention.

According to the invention, there is also provided a transfer member for use in forming a semiconductor layer, comprising: a heat-resistant substrate; and an oxide semiconductor layer comprising a large number of fine particles of an oxide semiconductor and a first electrode layer which are formed on the heat-resistant substrate in this order, in which when the first electrode layer formed on the heat-resistant substrate is bonded to any other member, and then the heat resistant substrate is peeled off, peeling occurs at a predetermined peeling interface so that the oxide semiconductor layer can uniformly be placed on the any other member via the first electrode layer.

According to this semiconductor layer-forming transfer member technique, a large number of fine particles of oxide semiconductor can be sintered at high temperature to from an oxide semiconductor layer, and oxide semiconductor layers of various sizes can be transferred to the transfer-receiving member with high accuracy, so that the electrically-conductive substrate of the invention can easily be produced.

In the method of producing the dye-sensitized solar cell substrate according to the invention, the oxide semiconductor layer-forming layer is formed via the intermediate layer-forming layer containing fine particles of metal oxide semiconductor so that adequate adhesion to the heat-resistant substrate and good peelability can be achieved when the intermediate membrane and the oxide semiconductor membrane are formed on the heat-resistant substrate. From the heat-resistant substrate, the intermediate membrane and the oxide semiconductor membrane can be placed with high accuracy onto another substrate, and thus the dye-sensitized solar cell substrate can be produced in high yield.

### BRIEF DESCRIPTION OF THE DRAWINGS

FIGS. 1A to 1D are process drawings for illustrating an example of the method of producing the dye-sensitized solar cell substrate of the invention;

FIGS. 2A to 2D are process drawings for illustrating an example of the method of producing the dye-sensitized solar cell of the invention;

FIG. 3 is a schematic cross-sectional view showing an example of the dye-sensitized solar cell produced by the method of the invention;

FIG. 4 is a schematic cross-sectional view showing another example of the dye-sensitized solar cell of the invention;

FIG. 5 is a process drawing for illustrating another example of the method of producing the dye-sensitized solar cell substrate of the invention;

FIG. 6 is a process drawing for illustrating yet another example of the method of producing the dye-sensitized solar cell substrate of the invention;

FIG. 7 is a process drawing for illustrating still another example of the method of producing the dye-sensitized solar cell substrate of the invention;

FIG. 8 is a cross-sectional view schematically showing an example of the electrically-conductive substrate of the invention;

FIG. 9 is a cross-sectional view schematically showing another example of the electrically-conductive substrate of the invention;

FIG. 10 is a cross-sectional view schematically showing yet another example of the electrically-conductive substrate of the invention;

FIG. 11 is a cross-sectional view schematically showing an example of the dye-sensitized solar cell electrode substrate of the invention; and

FIG. 12 is a schematic diagram showing an example of the cross-sectional structure of the dye-sensitized solar cell of the invention.

### DESCRIPTION OF THE PREFERRED EMBODIMENTS

A description is provided below of the method of producing a dye-sensitized solar cell substrate according to the invention, the method of producing a dye-sensitized solar cell with the dye-sensitized solar cell substrate, and the dye-sensitized solar cell substrate and the dye-sensitized solar cell produced by these methods.

A. Method of Producing Substrate for Dye-Sensitized Solar Cell

First, a description is provided of the method of producing a substrate for a dye-sensitized solar cell (a dye-sensitized solar cell substrate).

According to the invention, the method of producing the dye-sensitized solar cell substrate comprises the processes of:
applying, to a heat-resistant substrate, an intermediate layer-forming coating material that contains an organic material and fine particles of a metal oxide semiconductor and setting the coating to form an intermediate layer-forming layer (the process of forming an intermediate layer-forming layer);
applying, to the intermediate layer-forming layer, an oxide semiconductor layer-forming coating material whose solids have a higher concentration of fine particles of a metal oxide semiconductor than the concentration of the fine particles of the metal oxide semiconductor in the solids of the intermediate layer-forming coating material and setting the coating to form an oxide semiconductor layer-forming layer (the process of forming an oxide semiconductor layer-forming layer);
sintering the intermediate layer-forming layer and the oxide semiconductor layer-forming layer to form a porous intermediate membrane and a porous oxide semiconductor membrane (the sintering process); and
forming a first electrode layer and a substrate on the oxide semiconductor membrane (the electrode and substrate forming process).

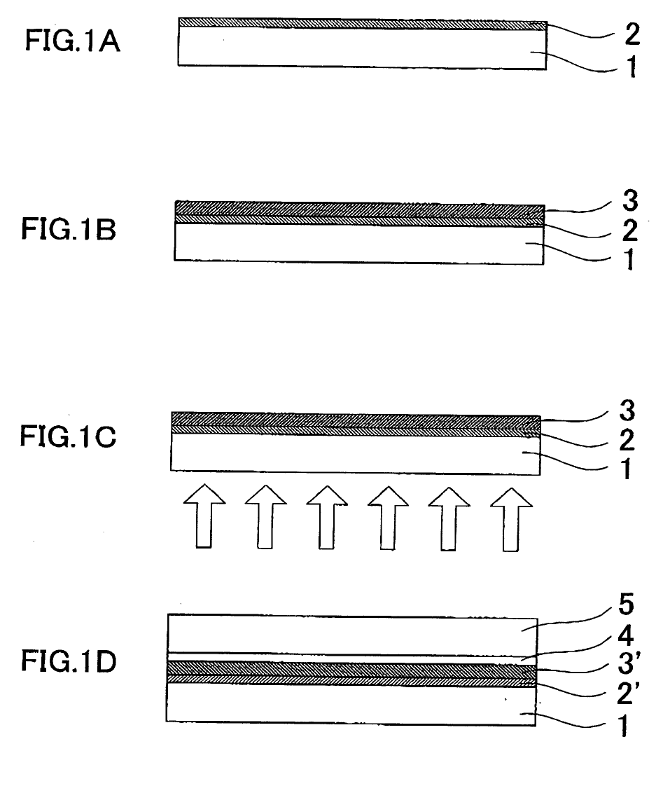

Referring to the drawings, the method of producing the dye-sensitized solar cell substrate according to the invention is described in detail below. FIGS. 1A to 1D are process drawings for illustrating an example of the method of producing the dye-sensitized solar cell substrate according to the invention. Referring to FIG. 1A, an intermediate layer-forming coating material is applied to a heat-resistant substrate 1 and set to form a intermediate layer-forming layer 2. Referring to FIG. 1B, an oxide semiconductor layer-forming coating material is applied to the intermediate layer-forming layer 2 and set to form an oxide semiconductor layer-forming layer 3.

Referring to FIG. 1C, the heat-resistant substrate 1 on which the intermediate layer-forming layer 2 and the oxide semiconductor layer-forming layer 3 are stacked is heated and sintered so that the intermediate layer-forming layer 2 and the oxide semiconductor layer-forming layer 3 are converted into porous products having continuous pores as shown in FIG. 1D. The porous products as formed are named an intermediate membrane 2′ and an oxide semiconductor membrane 3′, respectively.

Since the heat-resistant substrate 1 is used in the invention, sintering can be performed in a high temperature range so that binding of the fine particles of the metal oxide semiconductor can be sufficient in the process of forming the intermediate membrane 2′ and the oxide semiconductor membrane 3′. Additionally, since the oxide semiconductor layer-forming layer 3 is formed via the intermediate layer-forming layer 2 in the invention, the oxide semiconductor membrane 3′ can be formed with adequate adhesion to the heat-resistant substrate 31. This is for the reason as described below.

Conventionally, an oxide semiconductor membrane is formed on a heat-resistant substrate via an organic material membrane with no fine particles of metal oxide semiconductor. In the conventional case, cracking can easily occur after the sintering process between the organic membrane and the oxide semiconductor membrane because of a difference in thermal expansion coefficient between the organic material in the organic membrane and the fine particles of the metal oxide semiconductor in the oxide semiconductor membrane, and thus adhesion between the heat-resistant substrate and the oxide semiconductor membrane is very poor. In the invention, however, an oxide semiconductor layer-forming layer is formed via an intermediate layer-forming layer containing not only an organic material but also fine particles of metal oxide semiconductor, and therefore, the risk of cracking between the oxide semiconductor membrane and the heat-resistant substrate is very low even in the process of heating and sintering. Thus, the oxide semiconductor membrane can be formed with adequate adhesion to the heat-resistant substrate.

If the oxide semiconductor membrane is formed directly on the heat-resistant substrate with no intermediate membrane, the adhesion of the oxide semiconductor membrane to the heat-resistant substrate is very strong so that it can be difficult to peel off the heat-resistant substrate from the strongly adhering oxide semiconductor membrane in the process of placing the oxide semiconductor membrane onto another substrate from the heat-resistant substrate, and thus the oxide semiconductor membrane cannot be placed in a good manner on the substrate. In the invention, however, the oxide semiconductor layer-forming layer is formed via the intermediate layer-forming layer containing fine particles of metal oxide semiconductor, so that an oxide semiconductor membrane can be formed with high accuracy on a substrate because the membrane has not only adequate adhesion to the heat-resistant substrate but also good peelability.

Referring to FIG. 1D, a transparent electrode 4 is then formed on the oxide semiconductor membrane 3′, and a transparent substrate 5 is placed on the transparent electrode 4, so that a dye-sensitized solar cell substrate is produced. Using the heat-resistant substrate 1 as a protective layer, a dye-sensitized solar cell substrate with good durability and stability can be produced by a simple process.

A description is provided below of each process in the method of producing the dye-sensitized solar cell substrate of the invention.

1. Process of Forming Intermediate Layer-Forming Layer

A description is first provided of the process of forming the intermediate layer-forming layer. According to the invention, the process of forming the intermediate layer-forming layer includes applying an intermediate layer-forming coating material that contains an organic material and fine particles of a metal oxide semiconductor on the heat-resistant layer and setting it to form an intermediate layer-forming layer.

As used herein, the term “intermediate layer-forming layer” means a product produced by applying the intermediate layer-forming coating material and setting it. The term “intermediate membrane” as described below means a porous product formed by sintering the intermediate layer-forming layer. The term “intermediate layer” means a product comprising the porous intermediate membrane and a dye sensitizer fixed on the surface of the fine semiconductor particles of the intermediate membrane. When the dye-sensitized solar cell is produced with the dye-sensitized solar cell substrate according to the invention, the intermediate layer and the oxide semiconductor layer as described later form a photoelectric conversion layer which functions as a component for conducting, to the first electrode layer, the charge produced from the dye sensitizer by photoirradiation. Hereinafter, the term “photoelectric conversion layer” is also used to generically indicate the intermediate layer and the oxide semiconductor layer.

In the solids of the intermediate layer-forming coating material, the fine particles of the metal oxide semiconductor may have any concentration, as long as it is lower than the concentration of the fine particles of the metal oxide semiconductor in the solids of the metal oxide semiconductor layer-forming coating material as described later. For example, it is preferably in the range of 20% by weight to 80% by weight, more preferably in the range of 30% by weight to 70% by weight. If the intermediate layer-forming coating material contains the fine particles of the metal oxide semiconductor at a concentration in the above range, the oxide semiconductor membrane as described later can be formed with adequate adhesion to the heat-resistant substrate by forming an oxide semiconductor layer-forming layer via the intermediate layer-forming layer produced with the intermediate layer-forming coating material. In addition, the porous intermediate membrane formed by the sintering process as described later can have good peelability from the heat-resistant substrate, and thus both the intermediate membrane and the oxide semiconductor membrane can be formed with good quality on the dye-sensitized solar cell substrate.

While the concentration of the fine particles of the metal oxide semiconductor in the intermediate layer-forming coating material may depend on the coating method and the like, it is preferably in the range of 0.1% by weight to 15% by weight, more preferably in the range of 0.2% by weight to 12% by weight.

Any material that can conduct, to the first electrode layer, the charge produced from the dye sensitizer may be used for the fine particles of the metal oxide semiconductor. Examples of such materials include TiO₂, ZnO, SnO₂, ITO, ZrO₂, SI OX, MgO, Al₂O₃, CeO₂, Bi₂O₃, Mn₃O₄, Y₂O₃, WO₃, Ta₂O₅, Nb₂O₅, and La₂O₃. Fine particles of these metal oxide semiconductors are preferred because they are suitable for the production of the porous oxide semiconductor layer and can increase energy conversion efficiency and reduce costs. One of these materials or a mixture of two or more of these materials may be used for the fine particles. In particular, TiO₂ is preferably used. One of these materials may be used to form fine core particles, and any other material may be used to form a shell surrounding each of the fine core particles in a core-shell structure.

While the fine particles of the metal oxide semiconductor in the intermediate layer-forming coating material may have any diameter, they preferably have diameters in the range of 5 nm to 500 nm, more preferably in the range of 10 nm to 250 nm.

Any organic material may be used as long as it can be easily decomposed by the sintering process as described later. For example, the organic material is a resin, which may be any resin as long as it is resistant to dissolving in a solvent for use in forming the oxide semiconductor membrane as described later. Particularly in the invention, the resin preferably has a molecular weight in the range of 2000 to 600000, more preferably in the range of 10000 to 200000. The resin with a molecular weight in such a range can easily be decomposed by the sintering process as described later and can easily allow the production of the porous intermediate membrane with continuous pores from the intermediate layer-forming layer.

Specifically, a resin that can easily be thermally decomposed by sintering and will not remain in the intermediate membrane after sintering can preferably be used. Examples of such a resin include a cellulose resin such as ethyl cellulose, methyl cellulose, nitrocellulose, acetyl cellulose, acetyl ethyl cellulose, cellulose propionate, hydroxypropylcellulose, butyl cellulose, benzyl cellulose, and nitrocellulose; and an acrylic resin comprising a polymer or copolymer of methyl methacrylate, ethyl methacrylate, tert-butyl methacrylate, n-butyl methacrylate, isobutyl methacrylate, isopropyl methacrylate, 2-ethyl methacrylate, 2-ethylhexyl methacrylate, or 2-hydroxyethyl methacrylate; and polyhydric alcohols such as polyethylene glycol.

The content of the resin in the intermediate layer-forming coating material is preferably in the range of 0.01 to 15% by weight, more preferably in the range of 0.1 to 10% by weight.

If a solvent is contained in the intermediate layer-forming coating material, it should preferably be a good solvent for the organic material. The solvent should appropriately be selected mainly in view of its volatility and the solubility of the organic material for use. Examples of the solvent include ketones, hydrocarbons, esters, alcohols, halogenated hydrocarbons, glycol derivatives, ethers, ether esters, amides, acetates, ketone esters, glycol ethers, sulfones, and sulfoxides. One of these solvents or a mixture of two or more of these solvents maybe used. More preferred is such an organic solvent as acetone, methyl ethyl ketone, toluene, methanol, isopropyl alcohol, n-propyl alcohol, n-butanol, isobutanol, terpineol, ethyl cellosolve, butyl cellosolve, and butyl carbitol. If the intermediate layer-forming coating material contains such an organic solvent, it can have good wettability when applied to the heat-resistant substrate.

A variety of additives maybe used to improve the coatability of the intermediate layer-forming coating material. For example, a surfactant, a viscosity adjustor, a dispersing aid, a pH adjustor, and the like may be used as the additives. Examples of the pH adjustor include nitric acid, hydrochloric acid, acetic acid, dimethylformamide, and ammonia.

In this process, any known method of application may be used for the application of the intermediate layer-forming coating material. Examples of such a method include die coating, gravure coating, gravure reverse coating, roll coating, reverse roll coating, bar coating, blade coating, knife coating, air knife coating, slot die coating, slide die coating, dip coating, microbar coating, microbar reverse coating, and screen printing (rotary type). Using such a method of application, application and setting is performed once or more than once so that an intermediate layer-forming layer with the desired thickness can be formed.

While the intermediate layer-forming layer may have any thickness that allows the formation of the oxide semiconductor membrane with adequate adhesion to the heat-resistant substrate, it is preferably adjusted and defined such that it can provide the thickness as shown in a later section “3. Sintering Process” when it is made into a porous layer by the sintering process. For example, it preferably has a thickness in the range of 0.01 μm to 30 μm, more preferably in the range of 0.05 μm to 6 μm.

In this process, any material with good heat resistance may be used as the heat-resistant substrate. For example, the heat-resistant substrate may be made of glass, ceramic, or metal plate. When a heat-resistant substrate of such a material is used, the sintering process as described later can be performed at sufficiently high temperatures, so that strong binding of the fine particles of the metal oxide semiconductor can be achieved.

2. Process of Forming Oxide Semiconductor Layer-Forming Layer

Next, a description is provided of the process of forming the oxide semiconductor layer-forming layer. In the invention, the process of forming the oxide semiconductor layer-forming layer includes: applying, to the intermediate layer-forming layer, an oxide semiconductor layer-forming coating material whose solids contain the fine particles of the metal oxide semiconductor at a higher concentration than that of those in the solids of the intermediate layer-forming coating material; and setting the coating material to form an oxide semiconductor layer-forming layer.

As used herein, the term “oxide semiconductor layer-forming layer” means a product formed by applying an oxide semiconductor-forming coating material and setting it. The term “oxide semiconductor membrane” as described later means a porous product formed by sintering the oxide semiconductor layer-forming layer. The term “oxide semiconductor layer” means a product comprising a porous oxide semiconductor membrane and a dye sensitizer fixed on the surface of the fine semiconductor particles of the oxide semiconductor membrane. As mentioned above, when the dye-sensitized solar cell is produced, the oxide semiconductor layer and the intermediate layer form a photoelectric conversion layer which functions as a component for conducting, to the first electrode layer, the charge produced by photoirradiation from the dye sensitizer fixed on the surface of the fine semiconductor particles.

Like the intermediate layer-forming coating material, the oxide semiconductor layer-forming coating material for use in this process contains the fine particles of the metal oxide semiconductor. However, the concentration of the fine particles of the metal oxide semiconductor in the solids of the oxide semiconductor layer-forming coating material is adjusted to be higher than that of those in the solids of the intermediate layer-forming coating material. For example, the concentration of the fine particles of the metal oxide semiconductor in the solids of the oxide semiconductor layer-forming coating material is preferably in the range of 50% by weight to 100% by weight, more preferably in the range of 65% by weight to 90% by weight. If such an oxide semiconductor layer-forming coating material is used, the oxide semiconductor membrane formed as a porous product after the sintering process can hold a sufficient amount of the dye sensitizer on the surface of the fine semiconductor particles, so that the finally produced oxide semiconductor layer can sufficiently function to conduct the charge produced from the dye sensitizer by photoirradiation.

The concentration of the fine particles of the metal oxide semiconductor in the oxide semiconductor layer-forming coating material is preferably in the range of 15% by weight to 60% by weight, more preferably in the range of 20% by weight to 50% by weight. Using such an oxide semiconductor layer-forming coating material, the oxide semiconductor layer-forming layer with the desired thickness can be formed with high accuracy.

Since the same fine particles of the metal oxide semiconductor as shown in the section “1. Process of Forming Intermediate Layer-Forming Layer” can be used in this process, its description is not repeated here.

While the fine particles of the metal oxide semiconductor in the oxide semiconductor layer-forming coating material may have any diameter, they preferably have diameters in the range of 1 nm to 10 μm, more preferably in the range of 10 nm to 500 nm. It can be difficult to produce fine particles with diameters smaller than the above range, and if possible, such particles are not preferred because they can aggregate to each other to form secondary particles. Particles with diameters larger than the above range are not preferred because they can form an unnecessarily thick oxide semiconductor layer to increase the electrical resistance.

In the above particle diameter range, fine metal oxide semiconductor particles the same in type but different in diameter or fine metal oxide semiconductor particles different in type may be mixed before use. With such a mixture, the light scattering effect can be enhanced, and more light can be confined in the finally produced oxide semiconductor layer so that light absorption in the dye sensitizer can efficiently be performed. For example, a mixture may be used which includes fine metal oxide semiconductor particles with diameters in the range of 10 to 50 nm and fine metal oxide semiconductor particles with diameters in the range of 50 to 200 nm.

A resin can be used to form the oxide semiconductor layer-forming layer. Examples of such a resin include a cellulose resin, a polyester resin, a polyamide resin, a polyacrylate resin, a polyacrylic resin, a polycarbonate resin, a polyurethane resin, a polyolefin resin, a polyvinyl acetal resin, a fluororesin, and a polyimide resin, and polyhydric alcohols such as polyethylene glycol.

The content of the resin in the oxide semiconductor layer-forming coating material is preferably in the range of 0.5 to 20% by weight, more preferably in the range of 1 by weight to 10% by weight.

It a solvent is used for the oxide semiconductor layer-forming coating material, it may be any solvent as long as the resin can be dissolved in it and the organic material for use in forming the intermediate layer-forming layer can be resistant to dissolving in it. A variety of solvents may be used such as water, methanol, ethanol, isopropyl alcohol, propylene glycol monomethyl ether, terpineol, dichloromethane, acetone, acetonitrile, and ethyl acetate. In particular, water or an alcoholic solvent is preferred. As mentioned above, an organic solvent is preferably used for the intermediate layer-forming coating material. Thus, an aqueous solvent different from that of the intermediate layer-forming coating material is preferably used to form the oxide semiconductor layer-forming layer on the intermediate layer-forming layer, in order to prevent intermixing of both solvents.

A variety of additives may be used to improve the coatability of the oxide semiconductor layer-forming coating material. For example, a surfactant, a viscosity adjustor, a dispersing aid, a pH adjustor, and the like maybe used as the additives. Examples of the pH adjustor include nitric acid, hydrochloric acid, acetic acid, dimethylformamide, and ammonia. Examples of the dispersing aid include polymers such as polyethylene glycol, hydroxyethylcellulose, and carboxymethylcellulose; and surfactants, acids, and chelating reagents. In particular, polyethylene glycol is preferably added, because the viscosity of the dispersion can be adjusted by changing its molecular weight and it allows the production of a peel-resistant oxide semiconductor membrane and the control of the porosity of the oxide semiconductor membrane.

In this process, any known method of application may be used for the application of the coating material. Examples of such a method include die coating, gravure coating, gravure reverse coating, roll coating, reverse roll coating, bar coating, blade coating, knife coating, air knife coating, slot die coating, slide die coating, dip coating, microbar coating, microbar reverse coating, and screen printing (rotary type).

The oxide semiconductor layer-forming layer may have any thickness, as long as the finally produced oxide semiconductor layer can sufficiently function to conduct the charge produced from the dye sensitizer by photoirradiation. For example, it is preferably adjusted and defined such that it can provide the thickness as shown in the later section “3. Sintering Process” when it is made into a porous layer by the sintering process. For example, it preferably has a thickness in the range of 1 μm to 65 μm, more preferably in the range of 5 μm to 30 μm.

3. Sintering Process

A description is provided of the sintering process. The sintering process includes sintering the intermediate layer-forming layer and the oxide semiconductor layer-forming layer to produce a porous product so that an intermediate membrane and an oxide semiconductor membrane are formed.

In this process, the intermediate layer-forming layer and the oxide semiconductor layer-forming layer are sintered so that an intermediate membrane and an oxide semiconductor membrane can be formed as porous products having continuous pores.

In the invention, the oxide semiconductor layer-forming layer is formed via the intermediate layer-forming layer that contains the fine particles of the metal oxide semiconductor. Even after the sintering process is performed, therefore, cracking will hardly occur between the oxide semiconductor membrane and the heat-resistant substrate, and the oxide semiconductor membrane can be formed with good adhesion onto the heat-resistant substrate. The intermediate membrane containing the fine particles of the metal oxide semiconductor has good peelability from the heat-resistant substrate. Thus, the heat-resistant substrate can be peeled off in a good manner after the first electrode layer and another substrate are placed on the oxide semiconductor membrane in the electrode and substrate forming process as described later. Therefore, the dye-sensitized solar cell substrate can be produced in high yield.

In this process, the sintering temperature is preferably in the range of 300° C. to 700° C., more preferably in the range of 350° C. to 600° C. In the invention, the use of the heat-resistant substrate with good heat resistance allows sintering at temperatures in the above high range so that the intermediate membrane and the oxide semiconductor membrane can be formed with good binding of the fine particles of the metal oxide semiconductor.

In this process, sintering the intermediate layer-forming layer and the oxide semiconductor layer-forming layer may be performed by any heating method that allows uniform sintering of the intermediate layer-forming layer and the oxide semiconductor layer-forming layer without unevenness in heat. For example, any known heating method may be used.

The total thickness of the intermediate membrane and the oxide semiconductor membrane formed as porous products in this process is preferably in the range of 1 μm to 100 μm, more preferably in the range of 5 μm to 30 μm. In the intermediate membrane and the oxide semiconductor membrane produced by this process, the dye sensitizer is attached to the surface of the fine semiconductor particles, so that both membranes serves as a photoelectric conversion layer having the function of conducting the charge produced from the dye sensitizer by photoirradiation, when the dye-sensitized solar cell is used. If the total thickness of both membranes is within the above range, therefore, the membrane resistance of the photoelectric conversion layer can be small, and a sufficient amount of light absorption can be achieved.

The ratio of the thickness of the oxide semiconductor membrane to that of the intermediate membrane is preferably in the range of 10:0.1 to 10:5, more preferably in the range of 10:0.1 to 10:3. With the above total thickness of the intermediate membrane and the oxide semiconductor membrane, the thickness ratio between the oxide semiconductor membrane and the intermediate membrane in the above range allows adequate adhesion of the oxide semiconductor membrane formed on the heat-resistant substrate via the intermediate membrane. The intermediate layer-forming layer and the oxide semiconductor layer-forming layer are produced with coating materials different in the concentration of the fine metal oxide semiconductor particles in the solids. Thus, the intermediate membrane and the oxide semiconductor membrane produced by sintering these layers differ in porosity. Specifically, the oxide semiconductor membrane has a lower porosity than that of the intermediate membrane. In view of the relationship between their porosities and so on, the thickness ratio in the above range can ensure sufficient mechanical strength for the finally produced photoelectric conversion layer.

4. Electrode and Substrate Forming Process

A description is provided of the electrode and substrate forming process. This process includes forming the first electrode layer and the substrate on the oxide semiconductor membrane.

In this process, any material that has a high electrical conductivity and is not corroded by the electrolyte may be used to form the first electrode layer. In the dye-sensitized solar cell produced with the dye-sensitized solar cell substrate according to the invention, for example, the first electrode on the light-receiving side preferably has high light transparency. Examples of the high light transparency material include SnO₂, ITO, IZO, and ZnO. Fluorine-doped SnO₂ or ITO is more preferred, because of high electrical conductivity and high transparency.

It is also preferred that the material for the first electrode layer should be selected taking into account the work function or the like of the material for the second electrode layer, which is provided as a counter electrode when the dye-sensitized solar cell is produced with the dye-sensitized solar cell substrate prepared according to the invention. Examples of high work function materials include Au, Ag, Co, Ni, Pt, C, ITO, SnO₂, and fluorine-doped SnO₂ or ZnO. Examples of low work function materials include Li, In, Al, Ca, Mg, Sm, Tb, Yb, Zr, and LiF.

The first electrode layer may be a monolayer or a laminate of materials different in work function. Concerning the thickness of the first electrode layer, the thickness of the monolayer or the total thickness of the different layers is preferably in the range of 0.1 to 2000 nm, more preferably in the range of 1 nm to 500 nm.

In the invention, the first electrode layer maybe a laminate of different metal element layers. Examples thereof include a combination of a first electrode undercoat layer and a first electrode upper layer as used in the third embodiment described later.

A metal mesh having sufficient openings for light transparency may be placed on the substrate, or the metal mesh and the above material for the first electrode layer may be integrated or laminated, in order to form the first electrode layer according to the invention.

Any substrate including a transparent substrate and an opaque substrate may be used in this process. In the dye-sensitized solar cell produced with the dye-sensitized solar cell substrate prepared according to the invention, for example, the substrate on the light-receiving side should preferably have high light transparency. In addition, the substrate should preferably be excellent in heat resistance, weather resistance, and water vapor- or any other gas-barrier properties. Examples of the substrate include an inflexible rigid transparent substrate such as a quartz glass plate, a Pyrex (registered trademark) glass plate, and a synthetic quartz plate; and a plastic film such as an ethylene-tetrafluoroethylene copolymer film, a biaxially oriented polyethylene terephthalate film, a polyethersulfone (PES) film, a polyetheretherketone (PEEK) film, a polyetherimide (PEI) film, a polyimide (PI) film, and a polyester naphthalate (PEN) film. In the invention, the plastic film is more preferably used to form a film substrate, because it has good workability and can easily be used in combination with any other device and can find a wide range of applications. The plastic film is also effective in improving productivity and reducing manufacturing costs.

A single type of a film may be used alone, or two or more types of films may be laminated to form a composite film.

In this process, any method may be used in forming the first electrode layer and the substrate on the oxide semiconductor membrane. Examples of the method include a method comprising directly forming the first electrode layer on the oxide semiconductor membrane and then placing the substrate on the first electrode layer (first embodiment) and a method comprising previously preparing a substrate having the first electrode layer and transferring the oxide semiconductor membrane and the intermediate membrane onto the first electrode layer of the substrate (second embodiment).

In the first embodiment of this process, for example, the direct formation of the first electrode layer on the oxide semiconductor membrane may be achieved by each of the following specific processes: a process comprising: performing solution treatment in which a first electrode undercoat layer-forming coating material as described later is used to form a first electrode undercoat layer in the interior of or on the surface of the oxide semiconductor membrane; and forming a first electrode upper layer on the first electrode undercoat layer (third embodiment); and a process comprising using a first electrode layer-forming coating material as described later to form the first electrode layer on the oxide semiconductor membrane without performing the above-mentioned solution treatment (fourth embodiment). In this process, the placement of the substrate on the first electrode layer directly formed on the oxide semiconductor membrane according to the above embodiment of the method may include placing a substrate that comprises an electrically-conductive transparent inorganic layer and an electrically-conductive transparent organic-inorganic composite layer (fifth embodiment).

A description is provided below of each embodiment with respect to the method of forming the first electrode layer and the substrate in this process.

### (a) First Embodiment

In the first embodiment, the first electrode layer is directly formed on the oxide semiconductor membrane, and the substrate is then placed on the first electrode layer, so that the first electrode layer and the substrate are provided on the oxide semiconductor membrane.

In this embodiment, the timing of the formation of the first electrode layer is appropriately selected from before and after the sintering process, depending on the method of forming the first electrode layer. For example, the first electrode layer is preferably formed by wet coating before the sintering process. Specifically, a coating material for forming the first electrode layer is applied to the unsintered oxide semiconductor layer-forming layer, and the sintering process is then performed, so that the intermediate layer-forming layer and the oxide semiconductor layer-forming layer can be sintered together with the first electrode layer at the same time. Therefore, the first electrode layer can efficiently be formed on the oxide semiconductor membrane. After the sintering process, for example, the first electrode layer is preferably formed by a vapor deposition method, a sputtering method, a CVD method, or the like.

After the first electrode layer is formed as described above, the substrate is placed on the first electrode layer, so that the substrate for the dye-sensitized solar cell is produced. For example, the process of placing the substrate on the first electrode layer includes: providing a substrate that has a bonding layer for achieving good adhesion of the first electrode layer to the substrate; opposing the bonding layer and the first electrode layer to each other; and transferring the first electrode layer, the oxide semiconductor membrane and the intermediate membrane onto the substrate by a transfer method. In the invention, the oxide semiconductor membrane is formed on the heat-resistant substrate via the intermediate membrane so that the oxide semiconductor membrane can be formed with good adherence. Therefore, the first electrode layer, the oxide semiconductor membrane and the intermediate membrane can be transferred with high accuracy onto the substrate at a predetermined position.

The bonding layer and the transfer method are described later in the section of the second embodiment.

### (b) Second Embodiment

In the second embodiment, a substrate having the first electrode layer is previously provided, and the oxide semiconductor membrane and the intermediate membrane are then transferred onto the first electrode layer of the substrate, so that the first electrode layer and the substrate are placed on the oxide semiconductor membrane.

In this embodiment, any known method may be used to form the first electrode layer on the substrate, for example, including a wet coating method, a vapor deposition method, a sputtering method, and a CVD method. A vapor deposition method, a sputtering method and a CVD method are more preferred.

Any conventional transfer method may be used to transfer the oxide semiconductor membrane, the intermediate membrane and the like onto the substrate. For example, a heat transfer method or the like may be used.

When the oxide semiconductor membrane, the intermediate membrane and the like are transferred by the heat transfer method, any heating method may be used, for example, including a method with a heat bar, a method with a lamp, a method with a laser, an electromagnetic induction heating method, and an ultrasonic friction heating method. In the invention, a laser transfer method using a laser is more preferred. In this method, a solid-state laser (YAG laser), a semiconductor laser or the like may be used.

When the heat transfer method is used in this process, the heat transfer is preferably performed at a temperature lower than the glass transition temperature of the material of the transferred component such as the material of the oxide semiconductor membrane and the intermediate membrane, while the transfer temperature at the time of transfer may vary with the material of the transferred component. This is because the problem of a decrease in function by thermal degradation of the transferred components can be avoided.

In this process, a bonding layer may be provided on the substrate in order to improve the adhesion between the substrate and the first electrode layer, which will be directly formed on the substrate. Any material that can improve the adhesion between the substrate and the first electrode layer may be used to form the bonding layer, for example, including a heat sealing material, a pressure sensitive adhesive, an adhesive, a thermosetting resin, and an ultraviolet curable resin.

### (c) Third Embodiment

In the third embodiment, the process of directly forming the first electrode layer on the oxide semiconductor membrane according to the first embodiment includes: the process of a solution treatment in which a first electrode undercoat layer-forming coating material containing a dissolved metal salt or metal complex with a metal element for forming the first electrode layer is brought into contact with the oxide semiconductor membrane so that a first electrode undercoat layer is formed in the interior of or on the surface of the oxide semiconductor membrane; and the process of forming a first electrode upper layer on the first electrode undercoat layer.

In this embodiment, the first electrode undercoat layer is preferably formed after the sintering process, because after the porous product is formed, the first electrode undercoat layer-forming coating material can easily penetrate into the oxide semiconductor membrane.

In this embodiment, therefore, the first electrode undercoat layer-forming coating material can be infiltrated into the porous oxide semiconductor membrane so that the first electrode undercoat layer can be formed inside the oxide semiconductor membrane. In the following process of forming the first electrode upper layer, a dense first electrode layer can be formed by depositing the first electrode upper layer on the first electrode undercoat layer.

In this embodiment, the first electrode undercoat layer-forming coating material should preferably contain at least one of an oxidizing agent and a reducing agent. It is because an environment where the first electrode undercoat layer can easily be formed can be produced by the action of the oxidizing agent and/or the reducing agent.

A description is provided below of the solution treatment process and the process of forming the first electrode upper layer.

(I) Solution Treatment Process

In the solution treatment process according to this embodiment, the first electrode undercoat layer-forming coating material that contains a dissolved metal salt or metal complex having a metal element for forming the first electrode layer is brought into contact with the oxide semiconductor membrane so that a first electrode undercoat layer is formed in the interior of or on the surface of the oxide semiconductor membrane. A description is provided blow of each element of the solution treatment process.

(i) First Electrode Undercoat Layer-Forming Coating Material

First, a description is provided of the first electrode undercoat layer-forming coating material for use in this embodiment. The first electrode undercoat layer-forming coating material comprises a solvent and a metal salt or a metal complex (hereinafter they are also referred to as “metal source”) having at least a metal element for forming the first electrode, in which the metal salt or the metal complex is dissolved in the solvent.

Metal Source

The metal source for use in this embodiment may be any of a metal salt and a metal complex, as long as it contains a metal element for forming the first electrode layer and can form the first electrode undercoat layer. In the invention, the “metal complex” includes coordination compounds, in which an inorganic or organic matter(s) coordinates a metal ion(s), and so called organometallic compounds having a metal-carbon bond in their molecule.

The metal element of the metal source for use in the embodiment may be the same as “the material for forming the first electrode layer” as described above and thus its description is not repeated here.

The metal salt as the metal element supplier may be a metal element-containing chloride, nitrate, sulfate, perchlorate, acetate, phosphate, or bromate. In the invention, a chloride, a nitrate and an acetate are more preferably used, because these compounds are easily available as general purpose products.

Examples of the metal complex include magnesium diethoxide, aluminum acetylacetonate, calcium acetylacetonate dihydrate, calcium di(methoxyethoxide), calcium gluconate monohydrate, calcium citrate tetrahydrate, calcium salicylate dihydrate, titanium lactate, titanium acetylacetonate, tetraisopropyl titanate, tetra(n-butyl) titanate, tetra(2-ethylhexyl) titanate, butyl titanate dimer, titanium bis(ethylhexoxy)bis(2-ethyl-3-hydroxyhexoxide), diisopropoxytitanium bis(triethanolaminate), dihydroxybis(ammonium lactate) titanium, diisopropoxytitanium bis(ethylacetoacetate), titanium peroxo citrate ammonium tetrahydrate, dicyclopentadienyl iron(II), iron(II) lactate trihydrate, iron(III) acetylacetonate, cobalt(II) acetylacetonate, nickel(II) acetylacetonate dihydrate, copper(II) acetylacetonate, copper(II) dipivaloylmethanate, copper(II) ethylacetoacetate, zinc acetylacetonate, zinc lactate trihydrate, zinc salicylate trihydrate, zinc stearate, strontium dipivaloylmethanate, yttrium dipivaloylmethanate, zirconium tetra(n-butoxide), zirconium (IV) ethoxide, zirconium n-propylate, zirconium n-butylate, zirconium tetraacetylacetonate, zirconium monoacetylacetonate, zirconium acetylacetonate bis(ethylacetoacetate), zirconium acetate, zirconium monostearate, penta(n-butoxy) niobium, pentaethoxyniobium, pentaisopropoxyniobium, indium(III) tris(acetylacetonate), indium(III) 2-ethylhexanoate, tetraethyltin, dibutyltin(IV) oxide, tricyclohexyltin(IV) hydroxide, lanthanum acetylacetonate dihydrate, tri(methoxyethoxy)lanthanum, pentaisopropoxytantalum, pentaethoxytantalum, tantalum(V) ethoxide, cerium(III) acetylacetonate n(hydrate), lead(II) citrate trihydrate, and lead cyclohexanebutyrate. In the embodiment, preferably used are magnesium diethoxide, aluminum acetylacetonate, calcium acetylacetonate dihydrate, titanium lactate, titanium acetylacetonate, tetraisopropyl titanate, tetra(n-butyl) titanate, tetra(2-ethylhexyl) titanate, butyl titanate dimer, diisopropoxytitanium bis (ethylacetoacetate), iron (II) lactate trihydrate, iron(III) acetylacetonate, zinc acetylacetonate, zinc lactate trihydrate, strontium dipivaloylmethanate, pentaethoxyniobium, indium(III) tris(acetylacetonate), indium(III) 2-ethylhexanoate, tetraethyltin, dibutyltin(IV) oxide, lanthanum acetylacetonate dihydrate, tri(methoxyethoxy)lanthanum, and cerium(III) acetylacetonate n(hydrate).

In the embodiment, the first electrode undercoat layer-forming coating material may contain two or more of the above metal elements. Using different metal elements, a first electrode composite undercoat layer can be produced such as ITO, Gd—CeO₂, Sm—CeO₂, and Ni—Fe₂O₃.

While the concentration of the metal source is not limited as long as it allows the production of the first electrode undercoat layer, it is generally from 0.001 to 1 mol/l, preferably from 0.01 to 0.1 mol/l in the case of the metal salt, and generally from 0.001 to 1 mol/l, preferably from 0.01 to 0.1 mol/l in the case of the metal complex. If the concentration is lower than the above range, the first electrode undercoat layer can inadequately be formed so that it cannot contribute to the densification. If the concentration is higher than the above range, the resulting first electrode undercoat layer can be uneven in thickness.

Oxidizing Agent

In this embodiment, the oxidizing agent used in the first electrode undercoat layer-forming coating material has the function of promoting the oxidation of the metal ion or the like derived from the dissolved metal source. An environment where the first electrode undercoat layer can easily develop can be created by changing the valence of the metal ion or the like.

While the concentration of the oxidizing agent is not limited as long as it allows the production of the first electrode undercoat layer, it is generally from 0.001 to 1 mol/l, preferably from 0.01 to 0.1 mol/l. If the concentration is lower than the above range, the oxidizing agent can have no effect. Concentrations higher than the above range are not preferred in view of costs because of no significant increase in the effect.

Any oxidizing agent soluble in the solvent as shown below and capable of promoting the oxidation of the metal ion or the like may be used. Examples of such an oxidizing agent include hydrogen peroxide, sodium nitrite, potassium nitrite, sodium bromate, potassium bromate, silver oxide, dichromic acid, and potassium permanganate. In particular, hydrogen peroxide and sodium nitrite are preferably used.

Reducing Agent

In this embodiment, the reducing agent used in the first electrode undercoat layer-forming coating material serves to release electrons in a decomposition reaction, to produce hydroxide ions by electrolysis of water, and to raise the pH of the first electrode undercoat layer-forming coating material. If the pH of the first electrode undercoat layer-forming coating material is raised, an environment where the first electrode undercoat layer can easily develop can be created.

While the concentration of the reducing agent is not limited as long as it allows the production of the first electrode undercoat layer, it is generally from 0.001 to 1 mol/l, preferably from 0.01 to 0.1 mol/l in the case where the metal source is a metal salt, and generally from 0.001 to 1 mol/l, preferably from 0.01 to 0.1 mol/l in the case where the metal source is a metal complex. If the concentration is lower than the above range, the reducing agent can have no effect. Concentrations higher than the above range are not preferred in view of costs because of no significant increase in the effect.

Any reducing agent soluble in the solvent as shown below and capable of releasing electrons in a decomposition reaction may be used. Examples of such a reducing agent include a borane complex such as a borane-tert-butylamine complex, a borane-N,N-diethylaniline complex, a borane-dimethylamine complex, and a borane-trimethylamine complex, sodium cyanoborohydride, and sodium borohydride. In particular, the borane complex is preferably used.

In this embodiment, the reducing agent may be used in combination with the oxidizing agent to form an environment where the first electrode undercoat layer can easily be formed. Examples of such a combination of the reducing agent and the oxidizing agent include, but are not limited to, a combination of hydrogen peroxide or sodium nitrite and any reducing agent and a combination of any oxidizing agent and a borane complex. A combination of hydrogen peroxide and a borane complex is more preferred.

Solvents

In this embodiment, any solvent in which the metal salt or the like is soluble may be used in the first electrode undercoat layer-forming coating material. When the metal source is a metal salt, the solvent may be water, a lower alcohol with at most five total carbon atoms such as methanol, ethanol, isopropyl alcohol, propanol, and butanol, toluene, or any mixture thereof. When the metal source is a metal complex, the solvent may be the above lower alcohol, toluene, or a mixture thereof.

Additives

In this embodiment, the first electrode undercoat layer-forming coating material may contain an additive such as an auxiliary ion source and a surfactant.

The auxiliary ion source reacts with electrons to produce hydroxide ions, and thus it can raise the pH of the first electrode undercoat layer-forming coating material and can create an environment where the first electrode undercoat layer can easily be formed. The auxiliary ion source is preferably used in an amount properly selected depending on the metal salt or the reducing agent for use.

For example, the auxiliary ion source may be an ion species selected from the group consisting of chlorate ion, perchlorate ion, chlorite ion, hypochlorite ion, bromate ion, hypobromate ion, nitrate ion, and nitrite ion.

The surfactant acts on the interface between the first electrode undercoat layer-forming coating material and the substrate surface to facilitate the production of the metal oxide film on the substrate surface. The surfactant is preferably used in an amount properly selected depending on the metal salt and the reducing agent for use.

Examples of the surfactant include Surfynol series such as Surfynol 485, Surfynol SE, Surfynol SE-F, Surfynol 504, Surfynol GA, Surfynol 104A, Surfynol 104BC, Surfynol 104PPM, Surfynol 104E, and Surfynol 104PA (each manufactured by Nisshin Chemicals Co., Ltd.) and NIKKOL AM301 and NIKKOL AM313ON (each manufactured by Nikko Chemicals Co., Ltd.).

(ii) First Electrode Undercoat Layer

A description is provided of the first electrode undercoat layer, which is formed according to this embodiment. In this embodiment, the first electrode undercoat layer is formed by allowing the first electrode undercoat layer-forming coating material to contact the oxide semiconductor membrane.

The first electrode undercoat layer formed in the interior or the like of the oxide semiconductor membrane may have any structure as long as it can form the first electrode layer with the desired denseness by the later process of forming the first electrode upper layer. For example, the first electrode undercoat layer may exist from the inside to the surface of the oxide semiconductor membrane and may completely cover the oxide semiconductor membrane, or it may partially cover the surface of the oxide semiconductor membrane. For example, the first electrode undercoat layer partially covering the surface of the oxide semiconductor membrane may exist in the form of islands in the interior of the porous oxide semiconductor membrane.

(iii) Method of Bringing First Electrode Undercoat Layer-Forming Coating Material Into Contact With Oxide Semiconductor Membrane

A description is provided of the method of bringing the first electrode undercoat layer-forming coating material into contact with the oxide semiconductor membrane in this embodiment. In this embodiment, any method may be used to bring the first electrode undercoat layer-forming coating material into contact with the oxide semiconductor membrane. Examples of the contact method include a dipping method, a sheet-feed method, and a solution spray coating method.

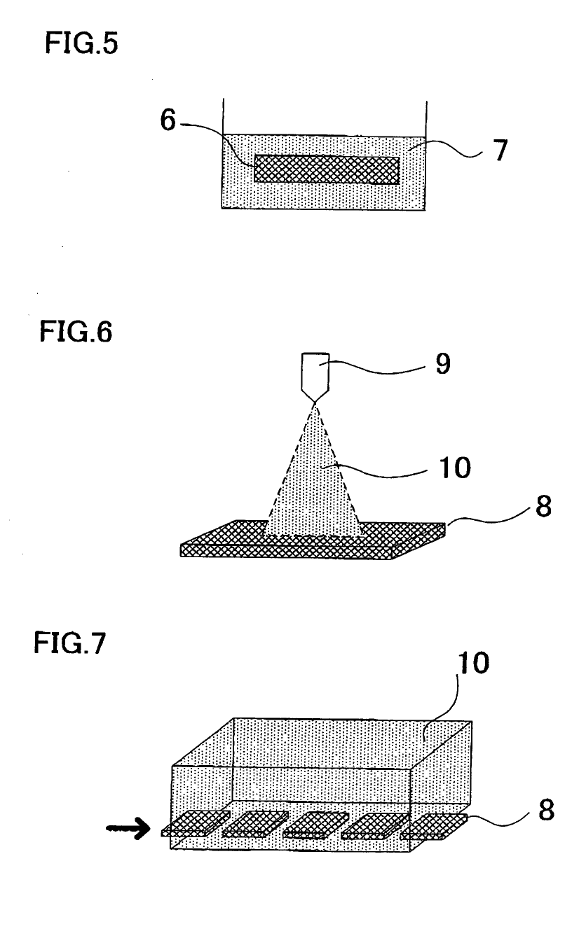

For example, the dipping method includes dipping, in the first electrode undercoat layer-forming coating material, the heat-resistant substrate with the oxide semiconductor membrane produced by the sintering process so that the first electrode undercoat layer is formed in the interior of or on the surface of the oxide semiconductor membrane. As shown in FIG. 5, for example, the heat-resistant substrate 6 with the oxide semiconductor membrane is dipped in the first electrode undercoat layer-forming coating material 7 when the first electrode undercoat layer is produced.

In this embodiment, heating is preferably performed when the oxide semiconductor membrane is allowed to contact the first electrode undercoat layer-forming coating material. Heating can enhance the activity of the oxidizing agent and the reducing agent and can increase the rate of formation of the first electrode undercoat layer. While any method may be used in heating, heating the oxide semiconductor membrane is preferred and heating the oxide semiconductor membrane and the first electrode undercoat layer-forming coating material is more preferred, because the reaction to form the first electrode undercoat layer can be facilitated in the vicinity of the oxide semiconductor membrane.

Such heating is preferably performed at a temperature properly selected depending on the feature of the oxidizing agent, the reducing agent or the like. For example, the heating temperature is preferably in the range of 50 to 150° C., more preferably in the range of 70 to 100° C.

(II) Process of Forming First Electrode Upper Layer

In this embodiment, the process of forming the first electrode upper layer includes forming the first electrode upper layer on the first electrode undercoat layer which is produced by the solution treatment as described above. In this embodiment, a dense first electrode layer can be produced by forming the first electrode upper layer on the first electrode undercoat layer.

Any method may be used to form the first electrode upper layer as long as it can form the first electrode upper layer with the desired denseness. Examples of such a method include a method comprising the steps of heating the first electrode undercoat layer after the solution treatment and bringing the first electrode upper layer-forming coating material (as described later) into contact with the undercoat layer to form the first electrode upper layer on the undercoat layer; a PVD method such as a vacuum deposition method, a sputtering method and an ion plating method; and a CVD method such as a plasma enhanced CVD method, a thermal CVD method, and an atmospheric pressure CVD method. More preferred is the method comprising the steps of heating the first electrode undercoat layer after the solution treatment and bringing the first electrode upper layer-forming coating material into contact with the undercoat layer to form the first electrode upper layer on the undercoat layer (hereinafter this method is also referred to as “spray method”). Such a spray method is described in detail below.

(i) Spray Method

The spray method is a process of forming the first electrode upper layer, which includes: heating the first electrode undercoat layer at a temperature equal to or higher than a metal oxide film-forming temperature; and bringing the undercoat layer into contact with the first electrode upper layer-forming coating material, which contains a dissolved metal salt or metal complex with a metal element for forming the first electrode layer, in order to form the first electrode upper layer on the undercoat layer.

In the spray method, the “metal oxide film-forming temperature” is a temperature at which the metal element contained in the first electrode upper layer-forming coating material can combine with oxygen to form a metal oxide film, which serves as the first electrode upper layer or the like. Such a temperature can significantly vary with the type of the metal ion or the like derived from the dissolved metal source, the composition of the first electrode upper layer-forming coating material and the like. In the spray method, the metal oxide film-forming temperature may be determined by the following method. A first electrode upper layer-forming coating material is experimentally prepared in which the desired metal source is dissolved. The coating material is then brought into contact with the heat-resistant substrate having the first electrode undercoat layer, while the heating temperature is changed. In this process, a lowest heating temperature is determined at which a metal oxide film serving as the first electrode upper layer is formed. The lowest heating temperature is defined as the metal oxide film-forming temperature in the spray method. In this process, whether or not the metal oxide film is formed is generally determined from the result of measurement with an X-ray diffractometer (RINT-1500 manufactured by Rigaku Corporation), and any amorphous film with no crystallinity is generally determined from the result of measurement with a photoelectron spectrometer (ESCALAB 200i-XL manufactured by V. G. Scientific).

In the spray method, while the first electrode undercoat layer is heated to a temperature equal to or higher than the metal oxide film-forming temperature, the undercoat layer is brought into contact with the first electrode upper layer-forming coating material to form the first electrode upper layer on the undercoat layer, so that a dense first electrode layer can be formed on the porous oxide semiconductor membrane.

Each element of the spray method is described below.

(i-i) First Electrode Upper Layer-Forming Coating Material

A description is first provided of the first electrode upper layer-forming coating material for use in the spray method. The first electrode upper layer-forming coating material comprises a solvent and a metal salt or a metal complex having a metal element for forming the first electrode layer, in which the metal salt or the metal complex is dissolved in the solvent.

In the spray method, the first electrode upper layer-forming coating material preferably contains at least one of an oxidizing agent and a reducing agent. At least one of the oxidizing agent and the reducing agent can reduce the heating temperature at which the first electrode upper layer is formed.

Metal Source

The metal source for use in the first electrode upper layer-forming coating material has a metal element (s) for forming the first electrode layer. Any of a metal salt and a metal complex may be used to form the first electrode upper layer. While the type of the metal source may be the same as the metal salt of the fist electrode undercoat layer-forming coating material in the solution treatment, a metal source capable of forming an electrically-conductive transparent first electrode upper layer is more preferred, because the first electrode upper layer acts as a collecting electrode in this embodiment. Examples of the metal oxide for forming the electrically-conductive transparent first electrode upper layer include, but are not limited to, ITO, ZnO, FTO (fluorine-doped tin oxide), ATO (antimony-doped tin oxide), and SnO₂ (TO). In the case of ITO, the metal source for forming such a metal oxide may be tris(acetylacetonato) indium(III), indium(III) 2-ethylhexanoate, tetraethyltin, dibutyltin(IV) oxide, or tricyclohexyltin(IV) hydroxide. In the case of ZnO, the metal source may be zinc acetylacetonate, zinc lactate trihydrate, zinc salicylate trihydrate, or zinc stearate. In the case of FTO, the metal source may be tetraethyltin, dibutyltin(IV) oxide, or tricyclohexyltin(IV) hydroxide. The fluorine doping agent may be ammonium fluoride or the like. In the case of ATO, the metal source may be antimony(III) butoxide, antimony(III) ethoxide, tetraethyltin, dibutyltin(IV) oxide, or tricyclohexyltin(IV) hydroxide. In the case of SnO₂ (TO), the metal source may be tetraethyltin, dibutyltin(IV) oxide, or tricyclohexyltin(IV) hydroxide.

The metal source for use in the first electrode upper layer-forming coating material is not limited as long as it can form the desired first electrode layer, and it may be the same as or different from the metal source for use in the first electrode undercoat layer-forming coating material. The combination of the first electrode upper layer and the first electrode undercoat layer is described later in the section “(i-ii) First Electrode Upper Layer,” and thus its description is not repeated here.

While the concentration of the metal source in the first electrode upper layer-forming coating material is not limited as long as it allows the production of the first electrode upper layer, it is generally from 0.001 to 1 mol/l, preferably from 0.01 to 0.5 mol/l in the case where the metal source is a metal salt, and generally from 0.001 to 1 mol/l, preferably from 0.01 to 0.5 mol/l in the case where the metal source is a metal complex. If the concentration is lower than the above range, it can take a long time to form the first electrode upper layer. If the concentration is higher than the above range, the resulting first electrode upper layer could be uneven in thickness.

Oxidizing Agent

The oxidizing agent used in the first electrode upper layer-forming coating material has the function of promoting the oxidation of the metal ion or the like derived from the dissolved metal source. An environment where the first electrode upper layer can easily develop can be created by changing the valence of the metal ion or the like, and in such an environment, the first electrode upper layer can be formed at a lower heating temperature. The concentration and type of such an oxidizing agent may be the same as that of the first electrode undercoat layer-forming coating material in the solution treatment as described above, and thus its description is not repeated here.

Reducing Agent

In the spray method, the reducing agent used in the first electrode upper layer-forming coating material serves to release electrons in a decomposition reaction, to produce hydroxide ions by electrolysis of water, and to raise the pH of the first electrode upper layer-forming coating material. If the pH of the first electrode upper layer-forming coating material is raised, an environment where the first electrode undercoat layer can easily develop can be created, and the first electrode upper layer can be formed at a lower heating temperature. The concentration and type of such a reducing agent may be the same as that of the first electrode undercoat layer-forming coating material in the solution treatment as described above, and thus its description is not repeated here.

In the spray method, the reducing agent may be used in combination with the oxidizing agent when the first electrode upper layer is formed. Examples of such a combination of the reducing agent and the oxidizing agent may be the same as that in the first electrode undercoat layer-forming coating material for the solution treatment as described above, and thus its description is not repeated here.

Solvents

Any solvent in which the metal salt or the like is soluble may be used in the first electrode upper layer-forming coating material. Such a solvent may be the same as the solvent of the first electrode undercoat layer-forming coating material for the solution treatment as described above, and thus its description is not repeated here.

Additives

In the spray method, the first electrode upper layer-forming coating material may contain an additive such as an auxiliary ion source and a surfactant. Such an additive may be the same as the additive of the first electrode undercoat layer-forming coating material for the solution treatment as described above, and thus its description is not repeated here.

(i-ii) First Electrode Upper Layer

A description is provided of the first electrode upper layer formed by the spray method. In the spray method, the first electrode upper layer is formed on the first electrode undercoat layer by heating the first electrode undercoat layer at a temperature equal to or higher than the metal oxide film-forming temperature and bringing the undercoat layer into contact with the first electrode upper layer-forming coating material, which contains a dissolved metal salt or metal complex with a metal element for forming the first electrode layer. A dense first electrode layer can be formed on the oxide semiconductor membrane by the solution treatment process and the first electrode upper layer-forming process as described above.

In the invention, while the combination of the metal oxide of the first electrode undercoat layer and the metal oxide of the first electrode upper layer is not limited as long as it can form the first electrode layer with the desired denseness, a combination of the metal oxides having crystal systems close to each other is preferred, and a combination of the metal oxides sharing a common metal element is more preferred.

For example, with an ITO film for the first electrode upper layer, the first electrode undercoat layer may be any material that allows the formation of a dense ITO film for the first electrode upper layer. Examples of such a material include ZnO, ZrO₂, Al₂O₃, Y₂O₃, Fe₂O₃, Ga₂O₃, La₂O₃, Sb₂O₃, ITO, In₂O₃, and SnO₂. Al₂O₃, Y₂O₃, Fe₂O₃, Ga₂O₃, La₂O₃, Sb₂O₃, ITO, In₂O₃, and SnO₂ are preferred because their crystal system is close to that of the ITO film. ITO, In₂O₃ and SnO₂ are more preferred because they share a common metal element (In, Sn) with the metal oxide film (ITO film).

(i-iii) Method of Bringing First Electrode Upper Layer-Forming Coating Material into Contact with First Electrode Undercoat Layer

A description is provided of the method of bringing the first electrode upper layer-forming coating material into contact with the first electrode undercoat layer according to the spray method. While any technique may be used to bring the first electrode undercoat layer into contact with the first electrode upper layer-forming coating material in the spray method, a contact method is preferably used in which a decrease in the temperature of the heated first electrode undercoat layer is prevented when the first electrode undercoat layer is brought into contact with the first electrode upper layer-forming coating material, because if the temperature of the first electrode undercoat layer is lowered, the first electrode layer could be formed in an undesired manner.

Examples of the method in which temperature decrease is prevented include, but are not limited to, a method of spraying droplets of the first electrode upper layer-forming coating material in bringing the first electrode undercoat layer into contact; and a method of allowing the first electrode undercoat layer to pass through a space containing a mist of the first electrode upper layer-forming coating material.

For example, the method of spraying the first electrode upper layer-forming coating material for contact may be a method of spraying it with a spray device or the like. Referring to FIG. 6, for example, such a method includes: heating the heat-resistant substrate 8 with the first electrode undercoat layer and so on to a temperature equal to or higher than the metal oxide film-forming temperature; and spraying the first electrode upper layer-forming coating material 10 from a spray device 9 to the substrate 8 to form the first electrode upper layer.

The droplets sprayed from the spray device generally have diameters of 0.1 to 1000 μm, preferably of 0.5 to 300 μm. If the diameters of the droplets are in the above range, temperature decrease can be suppressed so that a uniform first electrode upper layer can be formed. The spraying gas for the spray device may be air, nitrogen, argon, helium, oxygen, or the like. The spray rate of the spraying gas may be from 0.1 to 50 l/min, preferably from 1 to 20 l/min.

Referring to FIG. 7, the method of allowing the first electrode undercoat layer to pass through a space containing a mist of the first electrode upper layer-forming coating material may include: heating the substrate 8 having the first electrode undercoat layer to a temperature equal to or higher than the metal oxide film-forming temperature; and allowing the heated substrate 8 to pass through a space containing a mist of the first electrode upper layer-forming coating material 10 to form the first electrode upper layer. In this method, the droplets generally have diameters of 0.1 to 300 μm, preferably of 1 to 100 μm. If the diameters of the droplets are in the above range, temperature decrease can be suppressed so that a uniform first electrode upper layer can be formed.

In the spray method, the first electrode undercoat layer is heated to a temperature equal to or higher than the “metal oxide film-forming temperature,” when the first electrode upper layer-forming coating material is brought into contact with the heated first electrode undercoat layer. While the “metal oxide film-forming temperature” can significantly vary with the type of the metal ion or the like derived from the dissolved metal source, the composition of the first electrode upper layer-forming coating material and the like, it is generally in the range of 400 to 600° C., preferably in the range of 450 to 550° C., in the case where the first electrode upper layer-forming coating material does not contain the oxidizing agent and/or the reducing agent. On the other hand, it is generally in the range of 150 to 600° C., preferably in the range of 250 to 400° C., in the case where the first electrode upper layer-forming coating material contains the oxidizing agent and/or the reducing agent. It is preferably in the range of 300 to 500° C., more preferably in the range of 350 to 450° C. in the case where an ITO film is formed as the first electrode layer by the spray method.

Any heating method may be used, for example, including hot plate heating, oven heating, sintering furnace heating, infrared lamp heating, and hot air blower heating. It is more preferred that in the heating method, the first electrode undercoat layer is brought into contact with the first electrode upper layer-forming coating material while kept at the above-mentioned temperature, and specifically, a hot plate is preferably used.

(III) Method of Forming Substrate

In this embodiment, after the first electrode layer is formed by the above method, a substrate is placed on the first electrode layer to form a dye-sensitized solar cell substrate. The method of placing the substrate on the first electrode layer maybe the same as in the first embodiment, and thus its description is not repeated here.

### (e) Fourth Embodiment

In the fourth embodiment, the process of directly forming the first electrode layer on the oxide semiconductor membrane according to the first embodiment includes heating the oxide semiconductor membrane at a temperature equal to or higher than the metal oxide film-forming temperature and bringing the heated oxide semiconductor membrane into contact with a first electrode layer-forming coating material containing a dissolved metal salt or metal complex having a metal element for forming the first electrode layer in order to form the first electrode layer on the oxide semiconductor membrane.

In this embodiment, the spray method may be performed as in the third embodiment without the solution treatment, so that the first electrode layer can be formed on the porous oxide semiconductor membrane by a simple process. In this embodiment, the first electrode layer-forming coating material may be the same as the first electrode upper layer-forming coating material in the third embodiment, and the metal oxide film-forming temperature may be determined using the first electrode layer-forming coating material. In this embodiment, other features may also be the same as those in the third embodiment, except that the solution treatment is not performed, and thus their description is not repeated here.

### (f) Fifth Embodiment

The fifth embodiment, as a process of placing a substrate on the first electrode layer directly formed on the oxide semiconductor membrane according to the above embodiment, includes: providing a substrate comprising a transparent resin film, an electrically-conductive transparent inorganic layer and an electrically-conductive transparent organic-inorganic composite layer, in which the layers formed on the resin film; and placing the substrate in such a manner that the electrically-conductive transparent organic-inorganic composite layer is brought into contact with the first electrode layer.

The substrate used in this embodiment comprises a transparent resin film, an electrically-conductive transparent inorganic layer formed on the resin film and an electrically-conductive transparent organic-inorganic composite layer formed on the inorganic layer.

This embodiment has the advantage that lead electrodes can easily be connected using the electrically-conductive transparent inorganic layer or the like.

While any method may be used to form the first electrode layer on the oxide semiconductor membrane, the method according to the third or fourth embodiment is preferably used.

In this embodiment, the transparent resin film, the electrically-conductive transparent inorganic layer and the electrically-conductive transparent organic-inorganic composite layer may be the same as those of the “electrically-conductive substrate” as described later, and thus their description is not repeated here.

5. Other Elements

According to the invention, a dye sensitizer is fixed on the surface of the fine semiconductor particles of the porous intermediate membrane and the porous oxide semiconductor membrane to form a photoelectric conversion layer having the function of conducting the charge produced from the dye sensitizer by photoirradiation. The photoelectric conversion layer comprises: an intermediate layer that is formed by fixing the dye sensitizer on the surface of the fine semiconductor particles of the intermediate membrane; and an oxide semiconductor layer that is formed by fixing the dye sensitizer on the surface of the fine semiconductor particles of the oxide semiconductor membrane. In order to produce a high-photoelectric-conversion-efficiency dye-sensitized solar cell, the sensitizing dye should be fixed on as much porous portions as possible. It is therefore preferred that the sensitizing dye should be adsorbed on the inner surface of the pores of both the intermediate layer and the oxide semiconductor layer. In the same view, the sensitizing dye should preferably be fixed in the form of a monomolecular film on the porous portions.

Any dye sensitizer may be used as long as it can absorb light to produce an electromotive force. For example, an organic dye or a metal complex dye may be used as the dye sensitizer. Examples of organic dyes include acridine dyes, azo dyes, indigo dyes, quinone dyes, coumarin dyes, merocyanine dyes, and phenylxanthene dyes. Coumarin dyes are more preferred.

The metal complex dye is preferably ruthenium dyes, more preferably a ruthenium bipyridine dye or a ruthenium terpyridine dye, which is a ruthenium complex. The oxide semiconductor membrane can absorb little visible light (light about 400 to 800 nm in wavelength). For example, however, when a ruthenium complex is fixed on the oxide semiconductor membrane, the layer can significantly absorb visible light to cause photoelectric conversion, so that the light wavelength range in which photoelectric convention is possible can significantly be expanded.

In the invention, the process of fixing the dye sensitizer on the surface of the fine semiconductor particles of the intermediate membrane and the oxide semiconductor membrane may be performed at any time after the sintering process. For example, the fixing process may be performed immediately after the sintering process, before the electrode and substrate forming process is performed, or after the first electrode layer and the substrate are placed by the electrode and substrate forming process, the heat-resistant substrate may be peeled off and the fixing process may be performed.

Any method may be used to fix the dye sensitizer as long as it can fix the dye sensitizer on the surface of fine semiconductor particles of the intermediate membrane and the oxide semiconductor membrane. Examples of such a method include a method comprising dipping the oxide semiconductor membrane and the intermediate membrane in a dye sensitizer solution, infiltrating the solution and then drying the solution; and a method comprising applying a dye sensitizer solution to the oxide semiconductor membrane or the intermediate membrane, infiltrating the solution into both membranes, and then drying the solution.

In the above process, the dye sensitizer is fixed on the surface of the fine semiconductor particles of the porous intermediate membrane and the porous oxide semiconductor membrane to form a photoelectric conversion layer that can serve to conduct a charge which will be produced from the dye sensitizer by photoirradiation.

A protective layer is preferably formed on the intermediate membrane in the dye-sensitized solar cell produced with the dye-sensitized solar cell substrate according to the invention. Such protection of the intermediate membrane surface can suppress the influence of oxygen, water and the like and thus is effective in improving the durability and stability of the dye-sensitized solar cell substrate.

The heat-resistant substrate is preferably used as such a protective layer. After the electrode and substrate forming process, the heat-resistant substrate may be used as a protective layer without being peeled off, so that the dye-sensitized solar cell substrate can be protected from the influence of oxygen, water and the like at advantageous manufacturing efficiency and cost.

B. Method of Producing Dye-Sensitized Solar Cell

A description is provided of the method of producing the dye-sensitized solar cell according to the invention. The method of producing the dye-sensitized solar cell of the invention comprises the processes of:
forming a dye-sensitized solar cell substrate by the process as described above,
forming a second electrode layer and a counter substrate opposite to the first electrode and the substrate of the dye-sensitized solar cell substrate, and
forming an electrolyte layer between the second electrode layer and the photoelectric conversion layer comprising at least the intermediate layer and the oxide semiconductor layer which comprise the porous intermediate membrane, the porous oxide semiconductor membrane and the dye sensitizer fixed on the surface of the fine semiconductor particles of the porous intermediate membrane and the porous oxide semiconductor membrane.

As described above, the dye-sensitized solar cell substrate of the invention can be produced in high yield by the above process. Thus, the dye-sensitized solar cell can be produced advantageously in terms of quality and cost by using the dye-sensitized solar cell substrate and by forming the electrolyte layer, the second electrode layer, the counter substrate and the like.

Concerning the invention, each process is described in detail below.

1. Process of Forming Dye-Sensitized Solar Cell Substrate

In the method of producing the dye-sensitized solar cell of the invention, the process of forming the dye-sensitized solar cell substrate includes forming the dye-sensitized solar cell substrate by the above-described method according to the invention.

In this process, the above-described method is used to produce the dye-sensitized solar cell substrate comprising a substrate, a first electrode layer formed on the substrate and a photoelectric conversion layer which is formed on the first electrode layer and comprises a porous structure of fine particles of a metal oxide semiconductor and a dye sensitizer fixed on the surface of the fine particles, in which the photoelectric conversion layer conducts a charge produced from the dye sensitizer by photoirradiation.

This process may be the same as the process described above in the section “A. Method of Producing Substrate for Dye-Sensitized Solar Cell,” and thus its description is not repeated here.

2. Counter Electrode and Substrate Forming Process

A description is provided of the counter electrode and substrate forming process. The counter electrode and substrate forming process includes placing a second electrode layer and a counter substrate opposite to the first electrode layer and the substrate which are formed in the dye-sensitized solar cell substrate.

This process is performed before or after the electrolyte layer forming process depending on the manner of the electrolyte layer forming process as described later. This process may be performed after the electrolyte layer forming process, when the electrolyte layer is formed by applying an electrolyte layer-forming coating material to the intermediate layer of the photoelectric conversion layer of the dye-sensitized solar cell substrate and drying it (hereinafter such a method of forming an electrolyte layer is also referred to as “coating method”) in the process of producing the dye-sensitized solar cell. Alternatively, this process may be performed before the electrolyte layer-forming process when the electrolyte layer is formed by placing the intermediate layer of the photoelectric layer and the second electrode layer opposite to each other with a specific space provided between them and injecting an electrolyte layer-forming coating material into the space (hereinafter such a method of forming an electrolyte layer is also referred to as “injection method”) in the process of producing the dye-sensitized solar cell.

When the electrolyte layer is formed by the coating method as described later, the process of forming the second electrode layer and the counter substrate may include providing a counter substrate having a second electrode layer and bonding the counter substrate onto the electrolyte layer.

When the electrolyte layer is formed by the injection method as described later, the process of forming the second electrode layer and the counter substrate may include previously preparing a counter substrate having a second electrode layer and placing the dye-sensitized solar cell substrate and the second electrode layer-bearing substrate opposite to each other with a specific space provided between the intermediate layer and the second electrode layer.

In this case, the space between the intermediate layer and the second electrode layer is generally, but not limited to, in the range of 0.01 μm to 100 μm, preferably in the range of 0.1 μm to 50 μm. A space smaller than the above range is not preferred, because it can take a long time to inject the electrolyte layer-forming coating material into such a small space. A space larger than the above range is not preferred, because an unnecessarily thick electrolyte layer can be formed in such a large space.

When the intermediate layer and the second electrode layer are placed with a specific space between them, a spacer may be formed on any one of the substrate part of the dye-sensitized solar cell substrate and the counter substrate, in order to adjust the space to the desired value with high precision. Such a spacer may be any known glass spacer, resin spacer, or porous olefin film.

(a) Counter Substrate

In the invention, the counter substrate is placed opposite to the substrate that forms the dye-sensitized solar cell substrate. In the invention, while any substrate including a transparent substrate and an opaque substrate may be used as the counter substrate, the substrate on the light-receiving side should preferably have high light transparency. In addition, the substrate should preferably be excellent in heat resistance, weather resistance, and water vapor or any other gas-barrier properties.

The material specifically available for forming the counter substrate may be the same as that for the substrate part of the dye-sensitized solar cell substrate in the above process, and thus its description is not repeated here.

(b) Second Electrode Layer

In the invention, the second electrode layer is formed on the counter substrate and placed opposite to the first electrode layer formed in the dye-sensitized solar cell substrate.

Any material that has a high electrical conductivity and is not corroded by the electrolyte may be used to form the second electrode layer. The second electrode layer on the light-receiving side preferably has high light transparency. It is also preferred that the material for the second electrode layer should be selected taking into account the work function or the like of the material for the first electrode layer, which is opposed to the second electrode layer.

The material specifically available for forming the second electrode layer may be the same as that for the first electrode layer described in the section “A. Method of Producing Dye-Sensitized Solar Cell, 4. Electrode and Substrate Forming Process,” and thus its description is not repeated here.

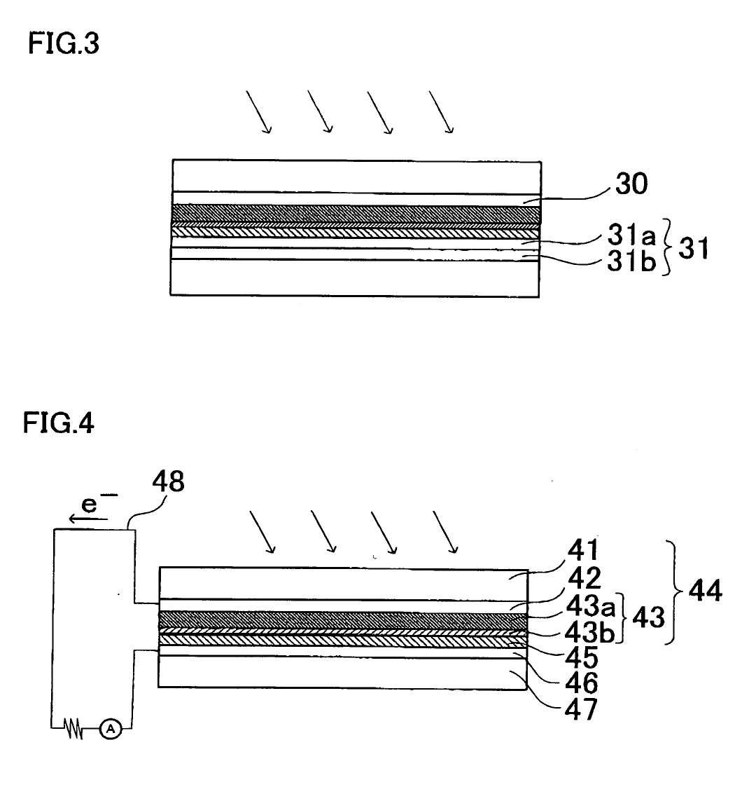

The second electrode layer may be a monolayer or a laminate of materials different in work function. Referring to FIG. 3, for example, when incident light is in the direction of the arrow, a transparent electrode is used as the first electrode layer 30, and a laminate of a vapor-deposited Pt layer 31a and an ITO layer 31b is used as the second electrode layer 31 opposite to the first electrode layer 30.

Concerning the thickness of the second electrode layer, the thickness of the monolayer or the total thickness of the different layers is preferably in the range of 0.1 to 500 mm, more preferably in the range of 1 nm to 300 nm.

3. Process of Forming Electrolyte Layer

In the invention, the process of forming the electrolyte layer includes forming the electrolyte layer between the photoelectric conversion layer and the second electrode layer.

The electrolyte layer formed by this process is located between the photoelectric conversion layer and the second electrode layer and performs charge transport when a charge is conducted by the photoelectric conversion layer and transported through the first and second electrode layers to the photoelectric conversion layer. The electrolyte layer is not limited as long as it has the above-mentioned function and may be in the form of any of a solid, a gel and a liquid.

For example, a gel electrolyte layer may be any of a physical gel and a chemical gel. The former can be formed by physical interaction around room temperature, and the latter can be formed by chemical bonding such as crosslinking.

While the electrolyte layer formed by this process may have any thickness, the total thickness of the photoelectric conversion layer and the electrolyte layer packed therein is preferably in the range of 2 μm to 100 μm, more preferably in the range of 2 μm to 50 μm. If the thickness is smaller than the above range, the photoelectric conversion layer could easily come into contact with the second electrode to cause a short circuit. If the thickness is greater than the above range, the internal resistance could be so high as to cause performance degradation.

As mentioned above, the electrolyte layer may be formed by the coating method which includes applying an electrolyte layer-forming coating material to the intermediate layer of the dye-sensitized solar cell substrate and drying it or by the injection method which includes placing the dye-sensitized solar cell substrate and the second electrode layer in such a manner that the intermediate layer of the photoelectric conversion layer is placed opposite to the second electrode layer with a specific space provided between them and then injecting an electrolyte layer-forming coating material into the space. A description is described below of each method of forming the electrolyte layer.

(a) Coating Method

A description is provided of the coating method in which the electrolyte layer is formed by applying an electrolyte layer-forming coating material and setting the coating. A solid electrolyte layer is generally formed by this method.

Any known method of application may be used in this coating method for applying the oxide semiconductor layer-forming coating material. Examples of such a known method include die coating, gravure coating, gravure reverse coating, roll coating, reverse roll coating, bar coating, blade coating, knife coating, air knife coating, slot die coating, slide die coating, dip coating, microbar coating, microbar reverse coating, and screen printing (rotary type).

Any electrolyte layer-forming coating material comprising at least a redox electrolyte and a macromolecule that retains the redox electrolyte may be used in the coating method.

The redox electrolyte may be any material conventionally used in electrolyte layers. For example, the redox electrolyte is preferably a combination of iodine and an iodide or a combination of bromine and a bromide. For example, the combination of iodine and an iodide includes a combination of I₂ and a metal iodide such as LiI, NaI, KI, and CaI₂. The combination of bromine and a bromide includes a combination of Br₂ and a metal bromide such as LiBr, NaBr, KBr, and CaBr₂.

The macromolecule for retaining the redox electrolyte is preferably CuI or a high hole-transportability conductive polymer such as polypyrrole and polythiophene.

The coating material may contain any other additive such as a crosslinking agent and a photo-polymerization initiator. After applied, the electrolyte layer-forming coating material containing such an additive may be cured by application of an activating light beam to form a solid electrolyte layer.

(b) Injection Method

A description is provided of the injection method in which the electrolyte layer is formed by injecting an electrolyte layer-forming coating material into the space between the intermediate layer and the second electrode layer.

A liquid, gel or solid electrolyte layer can be formed by such an injection method. For examples a gel electrolyte layer maybe any of a physical gel and a chemical gel. The former can be formed by physical interaction around room temperature, and the latter can be formed by chemical bonding such as crosslinking.

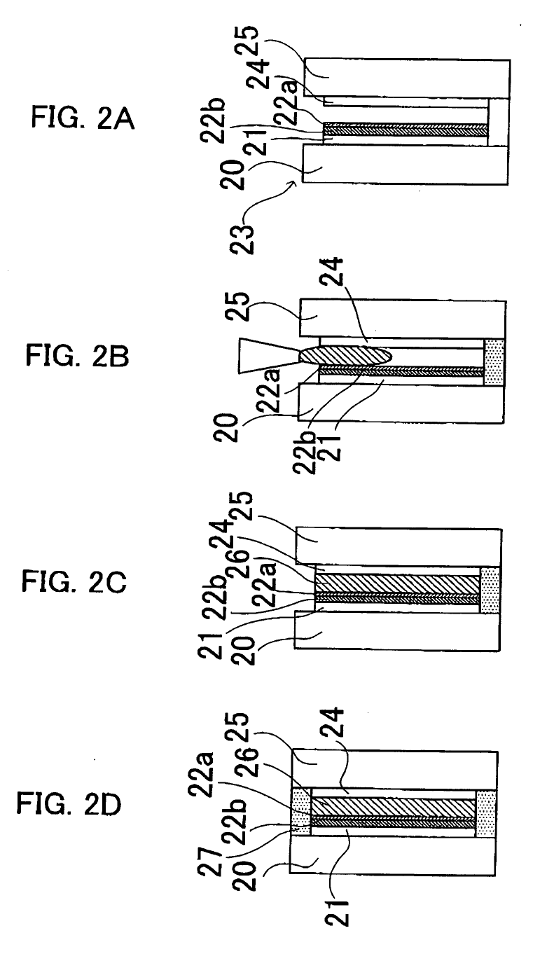

Referring to FIGS. 2A to 2D, a description is provided of an example of the method of producing the dye-sensitized solar cell of the invention in the case where the electrolyte layer is formed by the injection method. First, a dye-sensitized solar cell substrate 23 is provided which comprises a transparent electrode 21, an oxide semiconductor layer 22b and an intermediate layer 22a formed on the transparent substrate 20, and a counter substrate 25 having a second electrode layer 24 is provided. Referring to FIG. 2A, the dye-sensitized solar cell substrate 23 and the counter substrate 25 are placed in such a manner that the intermediate layer 22a is opposed to the second electrode layer 24 with a specific space provided between them.

Referring to FIG. 2B, the electrolyte layer-forming coating material is injected into the space formed between the intermediate layer 22a and the second electrode layer 24, so that an electrolyte layer 26 is formed between the intermediate layer 22a and the second electrode layer 24 as shown in FIG. 2C. When the electrolyte layer formed by the injection method is particularly in the form of a liquid or a gel, an organic polymer 27 or the like is provided for sealing as shown in FIG. 2D in order to prevent solvent vaporization, electrolyte layer leakage and the like, so that a dye-sensitized solar cell is completed.

In the process of forming the electrolyte layer by the injection method, any coating material that contains at least a redox electrolyte may be used as the electrolyte layer-forming coating material. For the formation of a gel electrolyte layer, the coating material should also contain a gelling agent. For a physical gel, the gelling agent may be polyacrylonitrile, polymethacrylate, or the like. For a chemical gel, the gelling agent may be an acrylate ester material, a metacrylate ester material or the like.

The redox electrolyte may be the same as used in the above-described coating method, and thus its description is not repeated here.

While any method capable of easily injecting a coating material may be used to inject the electrolyte layer-forming coating material into the space formed between the intermediate layer and the second electrode layer, an injection method using capillarity is typically used.

After the electrolyte layer-forming coating material is injected by the injection method, temperature control, ultraviolet irradiation, or electron beam irradiation may be done to cause a two- or three-dimensional crosslinking reaction so that a gel or solid electrolyte layer can be formed.

C. Substrate for Dye-Sensitized Solar Cell

A description is provided of the substrate for the dye-sensitized solar cell (the dye-sensitized solar cell substrate). The dye-sensitized solar cell substrate of the invention comprises a substrate; a first electrode layer formed on the substrate; and an oxide semiconductor layer formed on the first electrode layer, in which a metal element used as a component of the first electrode layer is detected in the oxide semiconductor layer, and the concentration of the metal element in the oxide semiconductor layer decreases in the direction from first electrode layer-side surface to opposite surface.

According to the invention, the metal element used as a component of the first electrode layer is detected in the corresponding region as stated above, so that the dye-sensitized solar cell can advantageously have a higher current-collecting efficiency.

For example, in the first, third and fourth embodiments of the invention as described in the section “4. Electrode and Substrate Forming Process,” a first electrode undercoat layer-forming coating material or the like is applied by wet coating so that the coating material can penetrate into the porous oxide semiconductor layer, and thus the metal element used as a component of the first electrode layer can exist in the oxide semiconductor layer of the resulting dye-sensitized solar cell substrate. Since the coating material comes from the first electrode layer side in the wet coating process, the concentration of the metal element in the oxide semiconductor layer decreases in the direction from first electrode layer-side surface to opposite surface, so that the metal element can have a concentration gradient across the oxide semiconductor layer of the resulting dye-sensitized solar cell substrate.

Whether or not the metal element used as a component of the first electrode layer exists in the oxide semiconductor layer can be determined by two-dimensional mapping of characteristic X-ray intensity of the metal element to be determined with an electron beam probe with respect to a cross section of the dye-sensitized solar cell substrate. Specifically, it can be determined using an EPMA (Electron Probe Micro Analyzer) manufactured by JEOL.

The concentration gradient of the metal element can be determined using a detected intensity profile in the ordinate direction (the vertical direction of the cross section) of the cross-sectional element mapping chart produced by the EPMA.

In the dye-sensitized solar cell substrate of the invention, the oxide semiconductor layer forms a photoelectric conversion layer, is a porous product containing fine particles of metal oxide semiconductor on which a dye sensitizer is fixed, and has the function of conducting a charge produced from the dye sensitizer by photoirradiation.

The photoelectric conversion layer preferably has an oxide semiconductor layer formed on the first electrode layer, and an intermediate layer having a higher porosity than that of the oxide semiconductor layer. A description is provided below of the case that the photoelectric conversion layer includes the intermediate layer.

As described above, the dye-sensitized solar cell substrate can be produced in high yield by the method of the invention. Thus, the use of the dye-sensitized solar cell substrate produced by the method of the invention is effective for high-yield production of the dye-sensitized solar cell.

In the dye-sensitized solar cell substrate of the invention, the photoelectric conversion layer is a porous layer which is formed on the first electrode layer and contains fine particles of metal oxide semiconductor. The photoelectric conversion layer has a surface on which a dye sensitizer is fixed, and it serves to conduct a charge produced from the dye sensitizer by photoirradiation. The photoelectric conversion layer has the oxide semiconductor layer and the intermediate layer. In the above-described method of producing the dye-sensitized solar cell substrate, the concentration of fine particles of metal oxide semiconductor in the solids differs between the intermediate layer-forming coating material and the oxide semiconductor layer-forming coating material. Thus, the photoelectric conversion layer formed by that process comprises at least two layers different in porosity. Specifically, the porosity of the intermediate layer is higher than that of the oxide semiconductor layer, because the concentration of fine particles of metal oxide semiconductor in the solids of the intermediate layer-forming coating material is lower than that of those in the solids of the oxide semiconductor layer-forming coating material.

While the photoelectric conversion layer comprises at least two layers different in porosity which include the oxide semiconductor layer and the intermediate layer, any other member different in porosity from the two layers may also be formed as needed in the above method of producing the dye-sensitized solar cell. In view of cost and the like, however, it is preferred that the photoelectric conversion layer should comprise the two layers: the oxide semiconductor layer and the intermediate layer.

For example, the intermediate layer preferably has porosity in the range of 25% to 65%, more preferably in the range of 30% to 60%. If the porosity of the intermediate layer is in the above range, the oxide semiconductor layer formed via the intermediate layer can have not only good adhesion to the heat-resistant substrate but also good peelability with respect to the heat-resistant substrate, so that the dye-sensitized solar cell can be produced with high accuracy. In the dye-sensitized solar cell produced by using the dye-sensitized solar cell substrate of the invention, if the porosity of the intermediate layer is in the above range, the electrolyte layer-forming coating material can easily penetrate into the oxide semiconductor layer through the intermediate layer in the process of forming the electrolyte layer between the intermediate layer and the second electrode layer, so that the electrolyte layer can sufficiently be formed in the pores of the porous photoelectric conversion layer, and thus a sufficient contact area can advantageously be established between them.

For example, the oxide semiconductor layer preferably has porosity in the range of 10% to 60%, more preferably in the range of 20% to 50%. If the porosity of the oxide semiconductor layer is in the above range, a sufficient amount of the dye sensitizer can be held in the pores of the oxide semiconductor layer, so that the function of the resulting photoelectric conversion layer can be sufficient to conduct the charge produced from the dye sensitizer in the dye-sensitized solar cell.

In the invention, the porosity refers to an unoccupied rate per unit volume with respect to the fine particles of metal oxide semiconductor. The above-stated porosity is determined based on the results of calculation from the weight per unit area of each photoelectric conversion layer and the specific gravity of the fine particles of metal oxide semiconductor. For example, when the intermediate layer and the oxide semiconductor layer are the same in fine particles of metal oxide semiconductor, the porosity of the intermediate layer can be determined as follows: The total weight and total thickness of the intermediate layer and the oxide semiconductor layer are determined, and then the weight and thickness of the oxide semiconductor layer are determined (by separately forming the oxide semiconductor layer only). From the results, the weight and thickness of the intermediate layer are calculated, and the weight per unit area of the intermediate layer is calculated, which is divided by the specific gravity of the fine particles of metal oxide semiconductor to give the porosity of the intermediate layer. The photoelectric conversion layer may have a thickness in the range of 1 μm to 100 μm, preferably in the range of 5 μm to 30 μm. In such a range, the photoelectric conversion layer has a small membrane resistance and can sufficiently absorb light.

The thickness ratio of the oxide semiconductor layer to the intermediate layer in the photoelectric conversion layer may be the same as stated in the section “A. Method of Producing Substrate for Dye-Sensitized Solar Cell, 3. Sintering Process,” and thus its description is not repeated here.

Other elements of the dye-sensitized solar cell substrate of the invention may be the same as described in the section “A. Method of Producing Substrate for Dye-Sensitized Solar Cell,” and thus their description is not repeated here.

D. Dye-Sensitized Solar Cell

A description is provided below of the dye-sensitized solar cell of the invention. According to the invention, the dye-sensitized solar cell comprises: a dye-sensitized solar cell substrate which comprises a substrate, a first electrode layer formed on the substrate, an oxide semiconductor layer formed on the first electrode layer, and an intermediate layer formed on the oxide semiconductor layer; a counter electrode substrate which comprises a counter substrate and a second electrode layer formed on the counter substrate, in which the second electrode layer is placed opposite to the intermediate layer; and an electrolyte layer placed between the intermediate layer and the second electrode layer, in which a metal element used as a component of the first electrode layer is detected in the oxide semiconductor layer, and the concentration of the metal element in the oxide semiconductor layer decreases in the direction from first electrode layer-side surface to opposite surface.

According to the invention, the metal element used as a component of the first electrode layer is detected in the corresponding region as stated above, so that the dye-sensitized solar cell can advantageously have a higher current-collecting efficiency. Whether or not the metal element used as a component of the first electrode layer exists in the oxide semiconductor layer may be determined in the same manner as described above in the section “C. Substrate for Dye-Sensitized Solar Cell,” and thus its description is not repeated here.

Referring to the drawings, the dye-sensitized solar cell of the invention is more specifically described below. FIG. 4 is a schematic cross-sectional view showing an example of the dye-sensitized solar cell of the invention. Referring to FIG. 4, it is used that a dye-sensitized solar cell substrate 44 comprises a transparent substrate 41, a transparent electrode 42 formed on the surface of the transparent substrate 41, and a photoelectric conversion layer 43 which are provided in this order from the incident light side indicated by the arrow. The photoelectric conversion layer 43 comprises an oxide semiconductor layer 43a and an intermediate layer 43b, in which the oxide semiconductor layer 43a is formed on the surface opposite to the light-incident side of the transparent electrode 42, and the intermediate layer 43b is formed on the surface opposite to the light-incident side of the oxide semiconductor layer 43a.

In the dye-sensitized solar cell substrate 44, the porosity of the intermediate layer 43b is higher than that of the oxide semiconductor layer 43a. Thus, in the process of forming an electrolyte layer 45 on the intermediate layer 43b side of the photoelectric conversion layer 43, the electrolyte layer 45 tends to penetrate into the pores from the intermediate layer 43b to the oxide semiconductor layer 43a, so that a sufficient contact area can be established between the electrolyte layer 45 and the photoelectric conversion layer 43.

On the surface opposite to the light-incident side of the electrolyte layer 45, a counter electrode 46 and a counter substrate 47 are placed opposite to the transparent electrode 42.

In this dye-sensitized solar cell, the charge produced from the dye sensitizer is used to produce a photocurrent. The charge produced from the dye sensitizer is generally an electron. The operating principle of the dye-sensitized solar cell is described below in the case where the charge produced from the dye sensitizer is an electron. Referring to FIG. 4, when light in the direction indicated by the arrow is let in, the dye sensitizer fixed on the photoelectric conversion layer 43 absorbs the light to be excited. The excited dye sensitizer generates electrons, which are transferred to the photoelectric conversion layer 43. The electrons are then transported to the counter electrode 46 through a lead 48 connected to the transparent electrode 42, so that a photocurrent can be obtained. The dye sensitizer is oxidized when it gives the generated electrons to the photoelectric conversion layer 43. The generated electrons are transferred to the counter electrode 46 and then reduce I₃⁻ to I^{- in the I}⁻/I₃⁻ redox pair contained in the electrolyte layer 45. I⁻ can reduce the oxidized dye sensitizer to its ground state.

In this dye-sensitized solar cell, each element may be the same as described above in the sections “A. Method of Producing Substrate for Dye-Sensitized Solar Cell,” “B. Method of Producing Dye-Sensitized Solar Cell” and “C. Substrate for Dye-Sensitized Solar Cell,” and thus its description is not repeated here. E. Electrically-Conductive Substrate, Electrode Substrate for Dye-Sensitized Solar Cell, Dye-Sensitized Solar Cell, and Transfer Member for Use in Forming Semiconductor Layer.

Referring to necessary drawings, a description is provided below of some modes of the electrically-conductive substrate, the electrode substrate for the dye-sensitized solar cell, the dye-sensitized solar cell whose type is different from the above, and the transfer member for use in forming a semiconductor layer, each according to the invention.

Electrically-Conductive Substrate (First Mode)

As stated above, the electrically-conductive substrate of the invention comprises a substrate, and an electrically-conductive transparent inorganic layer, an electrically-conductive transparent organic-inorganic composite layer, a first electrode layer, and an oxide semiconductor layer which are formed on the substrate in this order.

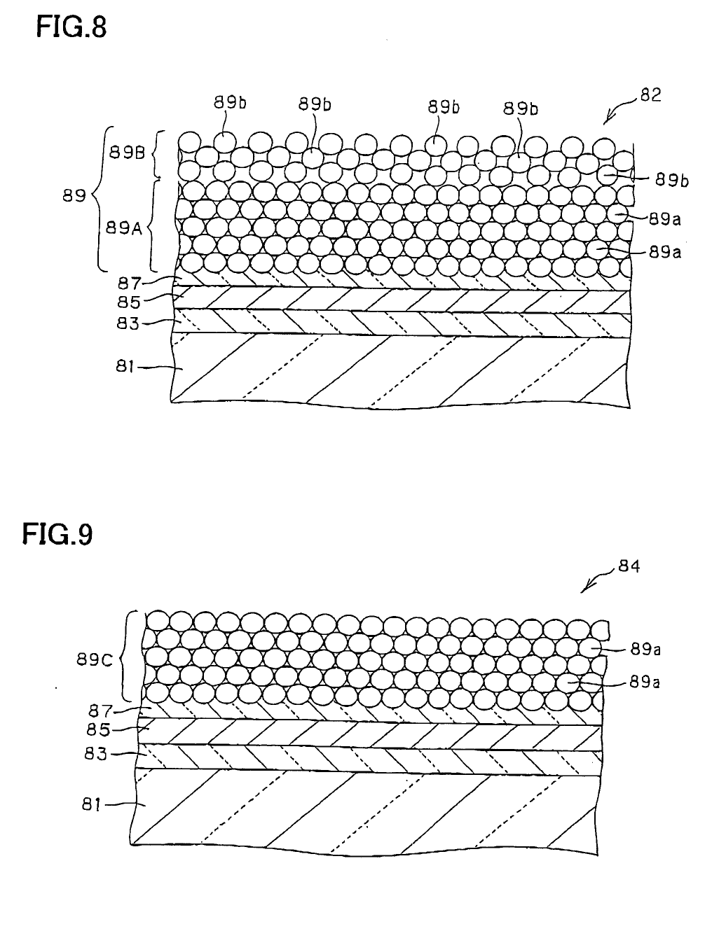

FIG. 8 is a cross-sectional view schematically showing an example of the electrically-conductive substrate of the invention. Referring to the drawing, an electrically-conductive substrate 82 includes a transparent film 81, an electrically-conductive transparent inorganic layer 83 formed on the transparent film 81, an electrically-conductive transparent organic-inorganic composite layer 85 formed on the inorganic layer 83, a first electrode layer 87 formed on the composite layer 85, and an oxide semiconductor layer 89 formed on the electrode layer 87. In FIG. 8, the oxide semiconductor layer 89 is not hatched for the sake of convenience. Each element is described in detail below.

(1) Transparent Resin Film

The transparent resin film 81 is a substrate necessary for making the electrically-conductive substrate 82 highly flexible. Depending on the use of the electrically-conductive substrate 82, the transparent resin film 81 may be selected from a variety of transparent resin films including a biaxially oriented polyethylene terephthalate film, an ethylene-tetrafluoroethylene copolymer film, a polyethersulfone film, a polyetheretherketone film, a polyetherimide film, a polyimide film, and a polyester naphthalate film. For example, when the electrically-conductive substrate 82 is for use as an electrode substrate component of a dye-sensitized solar cell, it should preferably be excellent in heat resistance, light resistance, weather resistance, gas barrier performance, or the like.

The transparent resin film 81 may have a mono layer structure or a laminated structure. The thickness of the transparent resin film 81 may be appropriately selected within the range of about 15 to 500 μm depending on the use of the electrically-conductive substrate 82. The light transmittance of the film is preferably about 80% or more in terms of visible overall optical transmittance.

(2) Electrically-Conductive Transparent Inorganic Layer

The electrically-conductive transparent inorganic layer 83 is one of the principal electrically-conductive layers in the electrically-conductive substrate 82. When the electrically-conductive substrate 82 is used as an electrode substrate for the dye-sensitized solar cell, it provides an electrically-conductive layer for receiving a lead electrode.

The electrically-conductive transparent inorganic layer 83 is formed of an electrically-conductive transparent inorganic material such as ITO, tin oxide, and fluorine-doped tin oxide, on the transparent resin film 81. When the electrically-conductive substrate 82 is used as an electrode substrate component for the dye-sensitized solar cell, the surface electrical resistance of the electrically-conductive transparent inorganic layer 83 is preferably about 50 Ω/square or less, more preferably about 20 Ω/square or less. It is preferred that the thickness of the electrically-conductive transparent inorganic layer 83 should properly be selected within the range of about 0.1 to 2 μm depending on the type of the electrically-conductive transparent inorganic material for use so as to give the desired electrical conductivity, flexibility and transparency. The electrically-conductive transparent inorganic layer 83 may be formed by a physical vapor deposition (PVD) method such as a vacuum deposition method, a sputtering method and an ion plating method, a chemical vapor deposition (CVD) method or the like depending on the material.

(3) Electrically-Conductive Transparent Organic-Inorganic Composite Layer

The electrically-conductive transparent organic-inorganic composite layer 85 is an important element for improving the flexibility (adhesion) of the oxide semiconductor layer 89 with respect to deformation of the electrically-conductive substrate 82. The electrically-conductive transparent organic-inorganic composite layer 85 is formed of an organic-inorganic composite material on the electrically-conductive transparent inorganic layer 83.

The organic-inorganic composite material may be a dispersion of an electrically-conductive inorganic material in a transparent resin. Examples of the transparent resin for the organic-inorganic composite material include a polyester, an ethylene-vinyl acetate copolymer, an acrylic resin, a polypropylene, a chlorinated polypropylene, a polyethylene, a vinyl chloride resin, a polyvinylidene chloride, a polystyrene, a polyvinyl acetate, a fluororesin, and a silicone resin.

These transparent resins may have any property of thermal plasticity, thermosetting property, photo (including ultraviolet)-curable property, electron beam-curable property, tackiness, and adhesive property. Flexible transparent resins are preferred to increase the flexibility of the electrically-conductive substrate 82. Thermoplastic transparent resins are more preferably used to allow heat sealing, when the first electrode layer 87 and the oxide semiconductor layer 89 are formed by the transfer method as described later. When the electrically-conductive substrate 82 is used as an electrode substrate component for the dye-sensitized solar cell, it should preferably be corrosion resistant to the electrolyte used in the dye-sensitized solar cell. A transparent resin that has a glass transition temperature lower than the heatproof temperature of the transparent resin film 81 and does not soften at the operating temperature of the electrically-conductive substrate 82 is preferably used to increase the productivity, durability and reliability of the electrically-conductive substrate 82.

Examples of the electrically-conductive inorganic material for the organic-inorganic composite material include fine particles, needles, rods, flakes and the like (hereinafter generically referred to as “electrically-conductive fine particles”) of a highly conductive inorganic material such as ITO, tin oxide, antimony-doped tin oxide (ATO), antimony oxide, gold, silver, and palladium. When the electrically-conductive fine particles are spherical, their diameters should preferably be selected within the range of about 5 to 1000 nm, more preferably in the range of about 10 to 500 nm as needed in view of their dispersibility, the light transmittance of the electrically-conductive organic-inorganic composite layer 5 and the like.

The electrically-conductive fine particles for the electrically-conductive transparent organic-inorganic composite layer 85 may be of a single type or two or more types. The content of the electrically-conductive fine particles in the electrically-conductive transparent organic-inorganic composite layer 85 may properly be selected depending on the type and shape of the electrically-conductive fine particles, the electrical conductivity of the electrically-conductive transparent inorganic layer 83, the type of the transparent resin of the electrically-conductive transparent organic-inorganic composite layer 85, and the thickness of the electrically-conductive organic-inorganic composite layer 85 in such a manner that the total surface electrical resistance of the electrically-conductive transparent organic-inorganic composite layer 85 and the electrically-conductive transparent inorganic layer 83 can be set within the desired range depending on the use of the electrically-conductive substrate 82 and the like and that the bonding strength between the electrically-conductive transparent organic-inorganic composite layer 85 and the first electrode layer 87 can be set within the desired range. When the electrically-conductive substrate 82 is used as an electrode substrate for the dye-sensitized solar cell, the content of the electrically-conductive fine particles is often selected within the range of about 5 to 50% by weight, particularly in the range of about 10 to 40% by weight, and the thickness of the electrically-conductive organic-inorganic composite layer 85 is often selected within the range of about 0.1 to 10 μm.

For example, the electrically-conductive transparent organic-inorganic composite layer 85 may be formed by a process including the steps of: preparing a coating material which is a dispersion of the electrically-conductive fine particles in a resin composition that can be set or cured to form the transparent resin by heat treatment or application of light (including ultraviolet light) or electron beam; applying the coating material to the electrically-conductive transparent inorganic layer 83 to form a coating film; and then setting or curing the coating film.

(4) First Electrode Layer

The first electrode layer 87 is provided to reduce the electrical resistance between the electrically-conductive transparent organic-inorganic composite layer 85 and the oxide semiconductor layer 89. If the first electrode layer 87 is provided, the electrical resistance between the electrically-conductive transparent organic-inorganic composite layer 85 and the oxide semiconductor layer 89 can be lower than the resistance generated by forming the oxide semiconductor layer 89 directly on the electrically-conductive transparent organic-inorganic composite layer 85.

For example, the material for the first electrode layer 87 may be the same as that for the electrically-conductive transparent inorganic layer 83 as illustrated above. When the electrically-conductive substrate 82 is used as an electrode substrate component for the dye-sensitized solar cell, the surface electrical resistance of the first electrode layer 87 is preferably about 50 Ω/square or less, more preferably about 20 Ω/square or less. It is preferred that the thickness of the first electrode layer 87 should properly be selected within the range of about 0.1 to 2 μm depending on the type of the electrically-conductive transparent inorganic material for use so as to give the desired electrical conductivity and transparency and such that the electrically-conductive substrate 82 can have high flexibility.

The first electrode layer 87 may be formed directly on the electrically-conductive transparent organic-inorganic composite layer 85 by a physical vapor deposition (PVD) method such as a vacuum deposition method, a sputtering method and an ion plating method or a chemical vapor deposition (CVD) method or may be formed together with the oxide semiconductor layer on the electrically-conductive transparent organic-inorganic composite layer 85 by the transfer method (see the later section “Method of Producing Electrically-Conductive Substrate”). The method of forming the first electrode layer as described in the section “A. Method of Producing Substrate for Dye-Sensitized Solar Cell” may also be used.

(5) Oxide Semiconductor Layer

The oxide semiconductor layer 89 comprises a large number of fine particles 89a and 89b of oxide semiconductor and is used as a photo-electrode when the electrically-conductive substrate 82 is used as an electrode substrate component of the dye-sensitized solar cell.

The oxide semiconductor layer 89 may have a monolayer structure or a multilayer structure of two or more layers. In some cases, the multilayer structure of the oxide semiconductor layer 89 cannot be identified from electron micrographs. In such cases, however, if two or more layers can be determined by the process or from their mechanical properties, the layers should be considered as forming “an oxide semiconductor layer of a multilayer structure” according to the description. Referring to FIG. 8, the oxide semiconductor layer 89 has a two-layer structure of first and second oxide semiconductor layers 89A and 89B comprising a large number of fine particles 89a and 89b of oxide semiconductor, respectively.

The fine oxide semiconductor particles 89a and 89b that form the oxide semiconductor layer 89 comprise an oxide semiconductor(s) capable of generating an electromotive force (a photo-electromotive force) upon exposure to light. Examples of such an oxide semiconductor include titanium oxide (TiO₂), zinc oxide (ZnO), tin oxide (SnO₂), magnesium oxide (MgO), aluminum oxide (Al₂O₃), cerium oxide (CeO₂), bismuth oxide (Bi₂O₃) manganese oxide (Mn₃O₄), yttrium oxide (Y₂O₃), tungsten oxide (W₂O₃), tantalum oxide (Ta₂O₅), niobium oxide (Nb₂O₅), and lanthanum oxide (La₂O₃).

The fine oxide semiconductor particles 89a and 89b are each preferably in the form of a sphere but may be in the form of a fine rod, needle, flake, or the like. In the invention, not only fine spheres of oxide semiconductor but also fine rods, needles, flakes, or the like are called “fine particles of oxide semiconductor (or fine oxide semiconductor particles).” In addition, blocks formed by fusion (necking) of fine particles of oxide semiconductor in the growth process may also be called “fine particles of oxide semiconductor (or fine oxide semiconductor particles).”

The fine oxide semiconductor particles 89a and 89b of the oxide semiconductor layer 89 may have the same composition or may be of two or more types in terms of composition, no matter whether they form a monolayer structure or a multilayer structure. In view of electric characteristics, safety and the like, the fine oxide semiconductor particles 89a and 89b preferably comprises titanium oxide or zinc oxide, more preferably anatase-type titanium oxide.

The size of the fine oxide semiconductor particles 89a and 89b may properly be selected within such a range that the oxide semiconductor layer 89 is available as a photo-electrode for the dye-sensitized solar cell, depending on their shape, no matter whether the oxide semiconductor layer 89 has a monolayer structure or a multilayer structure. When the fine oxide semiconductor particles 89a and 89b are spherical, their diameters are each preferably selected within the range of 5 nm to 100 nm, more preferably in the range of 10 nm to 70 nm.

When the oxide semiconductor layer 89 has a multilayer structure, the respective layers may be the same or different in the average size of the fine oxide semiconductor particles.

The average thickness of the oxide semiconductor layer 89 with the above structure is preferably in the range of about 1 to 30 μm, more preferably in the range of about 5 to 20 μm. In such case, for example, the oxide semiconductor layer 89 may be formed by the transfer method. The method of forming the oxide semiconductor layer 89 is described in detail in the later section “Method of Producing Electrically-Conductive Substrate.”

As described above, the oxide semiconductor layer 89 is formed on the electrically-conductive transparent inorganic layer 83 via the electrically-conductive transparent organic-inorganic composite layer 85 and the first electrode layer 87 in the electrically-conductive substrate 82 having the transparent resin film 81, the electrically-conductive transparent inorganic layer 83, the electrically-conductive transparent organic-inorganic composite layer 85, the first electrode layer 87, and the oxide semiconductor layer 89. According to such a structure, the electrically-conductive substrate 82 having the oxide semiconductor layer 89 can easily be produced in which the flexibility (adhesion) of the oxide semiconductor layer 89 to deformation is higher than that of an oxide semiconductor layer 89 formed directly on the electrically-conductive transparent inorganic layer 83 by the coating method.

The plan-view size of the electrically-conductive transparent inorganic layer 83 can be made larger than that of the oxide semiconductor layer 89, so that a lead electrode can easily be connected to the electrically-conductive transparent inorganic layer 83. Thus, even when the transfer method is used to form the oxide semiconductor layer 89 together with the first electrode layer 87, the oxide semiconductor layer 89 does not have to be partially removed for the formation of the lead electrode after the transfer process. If the electrically-conductive substrate 82 is used to form the dye-sensitized solar cell substrate, therefore, high processing accuracy would not be required and the risk of damage to the collecting electrode would be avoided in the process of forming the lead electrode. If the semiconductor layer-forming transfer member as described later is used, the first electrode 87 and the oxide semiconductor layer 89 can easily be formed in various sizes from small to large by the transfer method.

For these reasons, dye-sensitized solar cells with both high flexibility and high performance can easily be produced using the electrically-conductive substrate 82.

Electrically-Conductive Substrate (Second Mode)

The oxide semiconductor layer that forms the electrically-conductive substrate of the invention may have a monolayer structure or a multilayer structure as described in the above section on the first mode of the electrically-conductive substrate.

FIG. 9 is a cross-sectional view schematically showing an example of the electrically-conductive substrate of the invention in which the oxide semiconductor layer has a monolayer structure. Referring to the drawing, an electrically-conductive substrate 84 has the same structure as that of the electrically-conductive substrate 82 shown in FIG. 8, except that it does not have the second oxide semiconductor layer 89B. Thus, the same element is represented by the same reference numeral as used in FIG. 8, and its description is not repeated, except that the oxide semiconductor layer is represented by reference numeral 89C in FIG. 9.

The electrically-conductive substrate 84 is as effective as the electrically-conductive substrate 82 shown in FIG. 8 and may be produced in the same way as the electrically-conductive substrate 82 except that the oxide semiconductor layer 89C is formed as a monolayer.

Electrically-Conductive Substrate (Third Mode)

The electrically-conductive substrate of the invention may have a structure in which a protective member is placed on the oxide semiconductor layer.

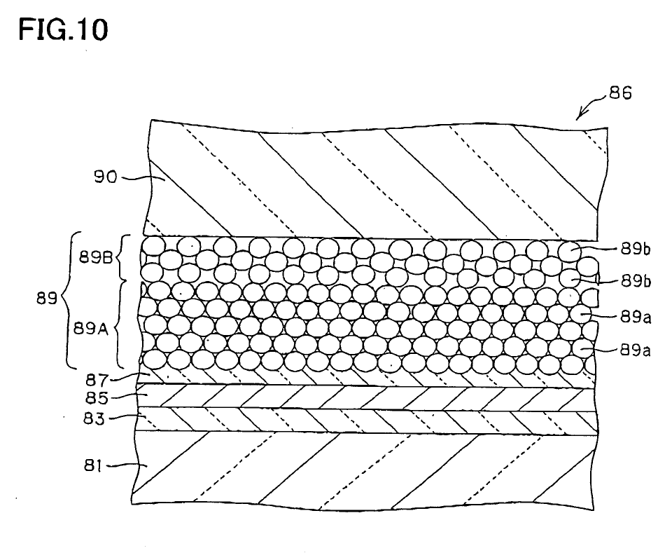

FIG. 10 is a cross-sectional view schematically showing an example of the electrically-conductive substrate having such a structure. Referring to the drawing, an electrically-conductive substrate 86 has the same structure as that of the electrically-conductive substrate 82 shown in FIG. 8 except that it has a protective member 90 placed on the oxide semiconductor layer 89. In FIG. 10, the same element is represented by the same reference numeral as used in FIG. 8, and its description is not repeated.

For example, a resin film may be used as the protective member 90. Alternatively, the heat-resistant substrate of the transfer member may be used as the protective member 90, when the oxide semiconductor layer 89 (particularly formed by sintering a large number of fine particles of oxide semiconductor at high temperature) is formed together with the first electrode layer 87 by the transfer method using the transfer member.

The resin film for use as the protective member 90 preferably has no stickiness or adhesive property. Of course, a sticky or adhesive resin film may be used as the protective member 90, but its stickiness or adhesive properties should preferably be very low, because if its stickiness or adhesive properties are high, the risk of damage to the oxide semiconductor layer 89 can be associated with the peeling process.

In the electrically-conductive substrate 86, the oxide semiconductor layer 89 is protected by the protective member 90 so that damage to the oxide semiconductor layer 89 can easily be prevented during transportation or distribution. The protective member 90 is peeled off before the electrically-conductive substrate 86 is used. When the transfer member as described later is used, the heat-resistant substrate serving as the protective member 90 can easily be peeled off by hand, and the electrically-conductive substrate 82 or 84 as shown in FIG. 8 or 9 can be obtained if the peeling interface is controlled in the transfer member.

For example, the electrically-conductive substrates in the first to third modes as described above may be produced by the method as described below.

Method of Producing Electrically-Conductive Substrate

In this method, the electrically-conductive substrate of the invention is formed by the processes of: preparing a laminate that includes a transparent resin film and an electrically-conductive transparent inorganic layer and an electrically-conductive transparent organic-inorganic composite layer or a layer in its uncured state which are staked in this order on a single side of the resin film (preparation process); and then transferring a first electrode layer and an oxide semiconductor layer onto the electrically-conductive transparent organic-inorganic composite layer or a layer in its uncured state (transfer process). The preparation process and the transfer process are described in detail below using necessary reference numerals of FIGS. 1 to 3.

(1) Preparation Process

As mentioned above, the laminate prepared by this process comprises a transparent resin film 81 and an electrically-conductive transparent inorganic layer 83 and an electrically-conductive transparent organic-inorganic composite layer 85 or a layer in its uncured state which are staked in this order on a single side of the resin film 81. The transparent resin film having the electrically-conductive transparent inorganic layer 83 on its one side may be a commercially available product or may be produced by forming the electrically-conductive transparent inorganic layer 83 on a side of the transparent resin film 81. The method of forming the electrically-conductive transparent inorganic layer 83 is described above in the section on the first mode of the electrically-conductive substrate, and its description is not repeated here.

The layer in the uncured state of the electrically-conductive transparent organic-inorganic composite layer 85 may be formed by applying a coating material to the electrically-conductive transparent inorganic layer, in which the coating material is prepared by dispersing the desired electrically-conductive fine particles in a resin composition such as a solvent-diluted resin composition that can be set to form a transparent thermoplastic resin by volatilizing the solvent, a thermosetting resin composition that can be cured to form a transparent resin by heating, a photo-curable resin composition that can be cured to form a transparent resin by application of light (including ultraviolet light), and an electron beam-curable resin composition that can be cured to form a transparent resin by application of an electron beam.

The electrically-conductive transparent organic-inorganic composite layer 85 can be produced by setting or curing the uncured state layer. The uncured state layer may be set or cured before or after the transfer of the first electrode layer 87 and the oxide semiconductor layer 89 or 89C depending on the material of the uncured state layer. For example, when the material of the uncured state layer is the solvent-diluted resin composition, the uncured state layer is set before the transfer to form the electrically-conductive transparent organic-inorganic composite layer. When the material of the uncured state layer is the thermosetting resin composition, the photo-curable resin composition, or the electron beam-curable resin composition, the uncured state layer is cured after the transfer to form the electrically-conductive transparent organic-inorganic composite layer. The content of the electrically-conductive fine particles in the electrically-conductive transparent organic-inorganic composite layer 85 and the thickness of the composite layer 85 are described in the above section on the first mode of the electrically-conductive substrate, and thus their description is not repeated here.

It is preferred that the electrically-conductive transparent organic-inorganic composite layer 85 produced with the coating material should have heat sealability, because if such a layer is used, the fist electrode layer 87 and the oxide semiconductor layer 89 or 89C can be formed with high transfer accuracy. For example, the heat-sealable electrically-conductive transparent organic-inorganic composite layer 85 may be formed by a process including the steps of: dispersing the desired electrically-conductive fine particles in a solvent-diluted resin composition that can be set to form a transparent thermoplastic resin by volatilizing the solvent so that a coating material is prepared; applying the coating material to the electrically-conductive transparent inorganic layer 83 to form a coating film; and then drying the coating film. In this case, the first electrode layer 87 and the oxide semiconductor layer 89 or 89C are transferred after the formation of the heat-sealable electrically-conductive transparent organic-inorganic composite layer 85.

The solvent-diluted resin composition may be produced by dissolving a solvent-soluble transparent thermoplastic resin in one or more solvents. When the electrically-conductive substrate of the invention is used as an electrode substrate component for the dye-sensitized solar cell, the solvent-soluble transparent thermoplastic resin should preferably be corrosion-resistant to the electrolyte for use in the dye-sensitized solar cell.

Any solvent capable of dissolving the solvent-soluble thermoplastic resin maybe used, for example, including ketones, hydrocarbons, esters, alcohols, halogenated hydrocarbons, glycol derivatives, ethers, ether esters, amides, acetates, ketone esters, glycol ethers, sulfones, and sulfoxides. Among these solvents, acetone, methyl ethyl ketone, toluene, methanol, isopropyl alcohol, n-propyl alcohol, n-butanol, isobutanol, terpineol, ethyl cellosolve, butylcellosolve, or butyl carbitol is preferably used to form a coating material with good wettability to the electrically-conductive transparent inorganic layer 83.

(2) Transfer Process

In the transfer process, the first electrode 87 and the oxide semiconductor layer 89 or 89C are formed by the transfer method on the electrically-conductive transparent organic-inorganic composite layer 85 or the layer in its uncured state. In order to form the oxide semiconductor layer 89 or 89C of large size and substantially uniform thickness on the electrically-conductive transparent organic-inorganic composite layer 85 via the first electrode layer 87, the process preferably includes: using the transfer member as mentioned below; press-bonding the transfer member to a heat-laminating electrically-conductive transparent organic-inorganic composite layer 85 under heating with a roller laminator or the like; and then peeling off the heat-resistant substrate from the transfer member so that the first electrode layer 87 and the oxide semiconductor layer 89 or 89C are placed. The electrically-conductive substrate 86 in the third mode can be produced by press-bonding the transfer member to the electrically-conductive transparent organic-inorganic composite layer 85 under heating, and then the electrically-conductive substrate 82 or 84 in the first or second mode can be produced by peeling off the heat-resistant substrate.

The transfer member may be the same as the dye-sensitized solar cell substrate described in the section “A. Method of Producing Substrate for Dye-Sensitized Solar Cell,” and thus its description is not repeated here. In this process, the first and second oxide semiconductor layers 89A and 89B correspond to the oxide semiconductor layer and the intermediate layer as described in the section “A. Method of Producing Substrate for Dye-Sensitized Solar Cell,” respectively.

Electrode Substrate for Dye-Sensitized Solar Cell

According to the invention, the electrode substrate for the dye-sensitized solar cell has the electrically-conductive substrate in the first or second mode and a sensitizing dye fixed on the oxide semiconductor layer of the electrically-conductive substrate.

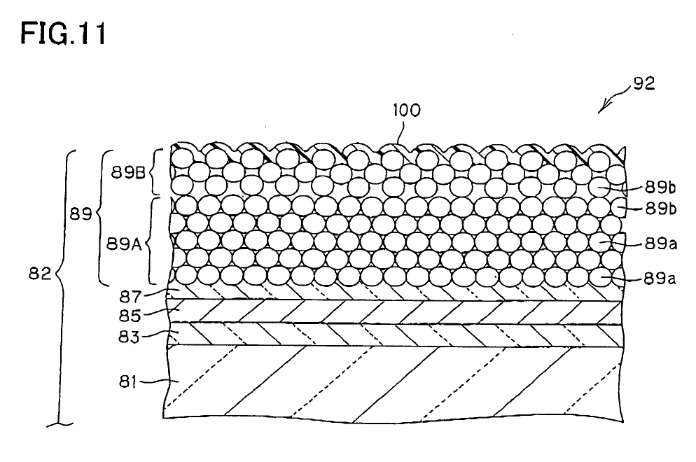

FIG. 11 is a cross-sectional view schematically showing an example of the electrode substrate for a dye-sensitized solar cell according to the invention. Referring to the drawing, an electrode substrate 92 for a dye-sensitized solar cell has a structure in which a sensitizing dye 100 is fixed on each of the first and second oxide semiconductor layers 89A and 89B of the electrically-conductive substrate 82 in the first mode as shown in FIG. 1.

While in FIG. 11 the sensitizing dye 100 is shown as a layer formed on the second oxide semiconductor layer 89 for the sake of convenience, actually, the sensitizing dye 100 is fixed on each of the surfaces of the first and second fine oxide semiconductor particles 89a and 89b of the first and second oxide semiconductor layers 89A and 89B.

The sensitizing dye 100 is provided to sensitize each of the first and second fine oxide semiconductor particles 89a and 89b. The sensitizing dye 100 is preferably (A) a dye whose absorption wavelength range extends to a longer wavelength range than that of each of the first and second fine oxide semiconductor particles 89a and 89b, (B) a dye that can have an electron energy level higher than the end of the conduction band of each of the first and second fine oxide semiconductor particles 89a and 89b when excited by light, or (C) a dye with which the time involved in injection of a carrier (electron) into the conduction band of the first or second fine oxide semiconductor particles 89a or 89b can be shorter than the time involved in re-trapping of the carrier from the conduction band of the first or second fine oxide semiconductor particles 89a or 89b.

Such a sensitizing dye 100 may be an organic dye or a metal complex dye. Examples of the organic dye include acridine dyes, azo dyes, indigo dyes, quinone dyes, coumarin dyes, merocyanine dyes, and phenylxanthene dyes Coumarin dyes are more preferred as the organic dye. The metal complex dye is preferably a ruthenium dye, more preferably a ruthenium bipyridine dye or a ruthenium terpyridine dye. These sensitizing dyes maybe used in the cell as described in the section “D. Dye-Sensitized Solar Cell” in the same manner.

In order to form a dye-sensitized solar cell with high photoelectric conversion efficiency, the fine oxide semiconductor particles 89a and 89b should preferably hold the sensitizing dye 100 as much as possible. Therefore, it is preferred that the sensitizing dye 100 should be adsorbed onto the inner surface of the pores of each of the first and second oxide semiconductor layers 89A and 89B. For the same purpose, the sensitizing dye 100 should preferably be fixed in the form of a monomolecular film on the fine oxide semiconductor particles 89a and 89b.

If the first and second oxide semiconductor layers 89A and 89B are each previously subjected to surface treatment, the transfer of the charge (which is once transferred from the sensitizing dye 100 to the first or second fine oxide semiconductor particles 89a or 89b) to the sensitizing dye 100 or the electrolyte of the dye-sensitized solar cell (the reverse electron transfer) can easily be prevented. After the sensitizing dye 100 is fixed, the oxide semiconductor layer 89A or 89B and the sensitizing dye 100 may be subjected to a specific treatment such as a treatment with a base such as tert-butyl pyridine when the fine oxide semiconductor particles 89a and 89b are titanium oxide, respectively and the sensitizing dye 100 is the ruthenium dye, so that a dye-sensitized solar cell which has high photoelectric conversion efficiency and is prevented from causing reverse electron transfer can be produced with the electrode substrate 92. These points may also be applied to the cell as described in the section “D. Dye-Sensitized Solar Cell.”

For example, the electrode substrate 92 for a dye-sensitized solar cell may be produced by preparing the electrically-conductive substrate 82 as described above and then fixing the sensitizing dye 100 on each of the first oxide semiconductor layer 89A (the first fine oxide semiconductor particles 89a) and the second oxide semiconductor layer 89B (the second fine oxide semiconductor particles 89b).

A solution of the sensitizing dye 100 (hereinafter referred to as “the dye solution”) is first prepared for the fixation of the sensitizing dye 100 on each of the first and second oxide semiconductor layers 89A and 89B. For the preparation, any one of an aqueous solvent and an organic solvent may properly be selected depending on the type of the dye. The dye solution is then applied to the second oxide semiconductor layer 89B by dipping the electrically-conductive substrate 82 in the dye solution or by applying or spraying the dye solution so that the first and second oxide semiconductor layers 89A and 89B are each impregnated with the dye solution. The penetrating dye solution is then dried so that the sensitizing dye 100 is fixed on each of the first oxide semiconductor layer 89A (the first fine oxide semiconductor particles 89a) and the second oxide semiconductor layer 89B (the second fine oxide semiconductor particles 89b), and thus the electrode substrate 92 for a dye-sensitized solar cell is obtained.

When the transfer method is used to form the first electrode layer 87, the first oxide semiconductor layer 89A (the oxide semiconductor layer) and the second oxide semiconductor layer 89B (the intermediate layer), the sensitizing dye may previously be fixed on each of the first and second oxide semiconductor layers of the transfer member as described above.

The electrode substrate 50 produced as described above can easily form a dye-sensitized solar cell with both high flexibility and high performance, because it is produced with the electrically-conductive substrate 82 of the invention as described above. Alternatively, the electrically-conductive substrate 84 in the second mode may be used in place of the electrically-conductive substrate 82 to form a dye-sensitized solar cell substrate, which can achieve the same effect.

Dye-Sensitized Solar Cell

The dye-sensitized solar cell of the invention comprises: a dye-sensitized solar cell substrate having an oxide semiconductor layer on which a sensitizing dye is fixed; a counter electrode substrate placed opposite to the dye-sensitized solar cell substrate; and an electrolyte layer placed between the dye-sensitized solar cell substrate and the counter electrode substrate, in which the dye-sensitized solar cell substrate comprises the above-described electrode substrate for the dye-sensitized solar cell according to the invention.

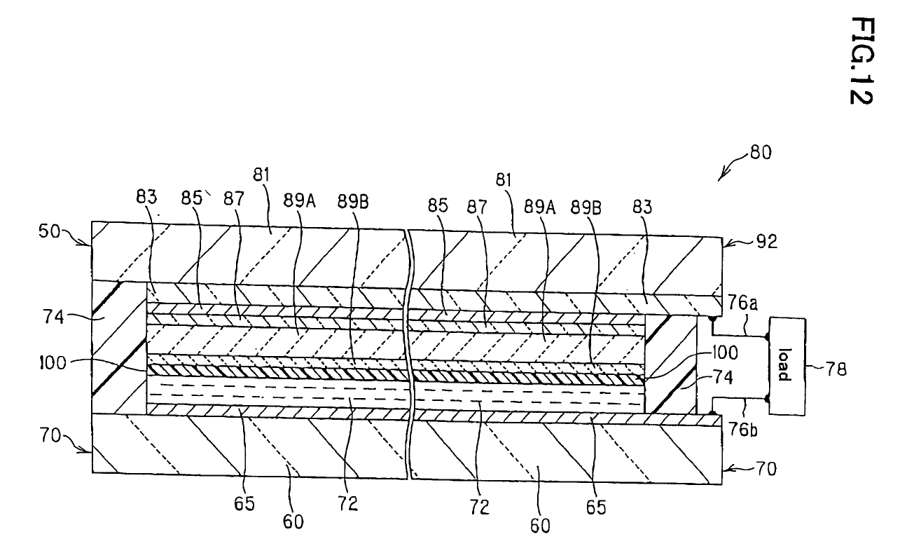

FIG. 12 is a schematic diagram showing an example of the cross-sectional structure of the dye-sensitized solar cell of the invention. Referring to the drawing, a dye-sensitized solar cell 80 uses the electrode substrate 92 as shown in FIG. 11. In the dye-sensitized solar cell 80, a counter electrode substrate 70 is placed opposite to the electrode substrate 92. An electrolyte layer 72 is interposed between the electrode substrate 92 and the counter electrode substrate 70, and the perimeter of the electrode layer 72 is sealed with a sealant 74.

In the electrode substrate 92, the first oxide semiconductor layer 89A (the oxide semiconductor layer) and the second oxide semiconductor layer 89B (the intermediate layer) are faced toward the electrolyte layer 72, and the electrically-conductive transparent inorganic layer 83, the electrically-conductive transparent organic-inorganic composite layer 85 and the first electrode layer 87 form a collecting electrode. The electrically-conductive transparent inorganic layer 83 is connected to a load (an external load) 78 through a lead 76a, and the load 78 is connected to the counter electrode 65 of the counter electrode substrate 70 through a lead 76b. The structure of the electrode substrate 92 is described above, and thus its description is not repeated here.

The counter electrode substrate 70 comprises a flexible substrate 60 and a counter electrode 65 formed on the substrate 70, in which the counter electrode 65 is placed to be in contact with the electrolyte layer 72. While the substrate 60 is preferably a resin film so as not to degrade the flexibility of the electrode substrate 92, a material having lower flexibility than that of the transparent resin film 81 of the electrode substrate 92 may also be used. In many cases, the outer surface of the transparent resin film 81 of the electrode substrate 92 is used to receive light in the dye-sensitized solar cell 80. In such cases, therefore, the substrate 60 does not have to be light-transparent.

The material for the counter electrode 65 may be platinum, gold, silver, carbon, an electrically-conductive inorganic oxide (such as ITO, ATO, tin oxide, and antimony oxide), or the like depending on the type of the electrolyte for the electrolyte layer 72. The counter electrode 65 may have a monolayer structure of a single type of electrically-conductive material or a multilayer structure of two or more layers in which adjacent layers differ in composition. When the electrolyte layer 72 is formed of a liquid electrolyte, the counter electrode 65 is preferably formed of an electrically-conductive material (e.g. platinum) that can function as a catalyst when one of the ion species forming a redox pair in the electrolyte reacts with a carrier during photoirradiation to form the other of the ion species, so that the photoelectric conversion efficiency of the dye-sensitized solar cell 80 can be increased. For example, the counter electrode 65 may be formed by a PVD method, a CVD method or the like, and its thickness may properly be selected within the range of about 1 to 1000 nm.

The electrolyte layer 72 is interposed between the dye-sensitized solar cell substrate 50 and the counter electrode substrate 70 and allows the formation of a closed circuit including the electrode substrate 92, the lead 76a, the load 78, the lead 76b, and the counter electrode substrate 70. The material for the electrolyte layer 72 may be selected from a variety of liquid electrolytes, cold-dissolved salt type liquid electrolytes, gel electrolytes, and solid electrolytes, which contain at least a redox pair for carrier transportation. In the case that a liquid electrolyte is used as the material for the electrolyte layer 72, the redox pair may be I⁻/I₃⁻, Br⁻/Br₃⁻, quinone/hydroquinone, or the like.

While the thickness of the electrolyte layer 72 may be selected as needed, it is preferred that the total of the average thicknesses of the electrolyte layer 72, the second oxide semiconductor layer 89B and the first oxide semiconductor layer 89A should be selected within the range of about 2 to 100 μm, particularly in the range of about 2 to 50 μm. If the thickness of the electrolyte layer 72 is too small beyond the above range, the electrode substrate 92 and the counter electrode substrate 70 can easily form a short circuit. If too large beyond the above range, the internal resistance of the dye-sensitized solar cell 80 can be so high as to cause performance degradation. The electrolyte layer 72 may be formed by any of various methods such as a coating method and an injection method depending on its material.

Spacers such as glass spacers, resin spacers and olefin-based porous films may be placed between the electrode substrate 92 and the counter electrode substrate 70 such that the distance between the electrode substrate 92 and the counter electrode substrate 70 can be kept at the desired distance with high accuracy for the prevention of short circuit. The spacers may previously be provided on any one of the electrode substrate 92 and the counter electrode substrate 70 or may be bonded to at least one of the electrode substrate 92 and the counter electrode substrate 70 when the dye-sensitized solar cell 80 is constructed. Part of the spacers may be used as the sealant 74.

The dye-sensitized solar cell 80 having the above structure uses the electrode substrate 92 of the invention (see FIG. 11). As described above, the electrode substrate 92 can easily form a dye-sensitized solar cell with both high flexibility and high performance. According to the structure of the dye-sensitized solar cell 80, therefore, both high flexibility and high performance can be achieved at the same time.

Alternatively, the sensitizing dye may be fixed on the oxide semiconductor layer 89C of the electrically-conductive substrate 84 in the second mode as shown in FIG. 9 to form an electrode substrate for a dye-sensitized solar cell. A dye-sensitized solar cell produced with such an electrode substrate would also be as effective as the dye-sensitized solar cell 80.

The above embodiments are not intended to limit the scope of the invention. The above embodiments should be regarded merely as examples. Any modifications or alterations having substantially the same elements and effects as those of the claimed invention will fall within the scope of the invention.

### EXAMPLES

The invention is more specifically described by means of the examples and the comparative examples below.

### Example 1-1

Preparation of Intermediate Layer-Forming Layer

An intermediate layer-forming coating material was prepared as follows. An acrylic resin comprising poly(methyl methacrylate) as a main component (with a molecular weight of 25000 and a glass transition temperature of 105° C.)(BR87 manufactured by Mitsubishi Rayon Co., Ltd.) was dissolved at a concentration of 1% by weight in methyl ethyl ketone and toluene with a homogenizer, and then fine particles of TiO₂ with a primary particle diameter of 20 nm (P25 manufactured by Nippon Aerosil Co., Ltd.) were dispersed therein at a concentration of 1% by weight to form an intermediate layer-forming coating material. The coating material was applied with a wire bar to an alkali-free glass substrate (with a thickness of 0.7 mm) provided as a heat-resistant substrate and then dried.

Preparation of Oxide Semiconductor Layer-Forming Layer

An oxide semiconductor layer-forming coating material was prepared as follows. Using a homogenizer, 37.5% by weight of fine particles of TiO₂ with a primary particle diameter of 20 nm (P25 manufactured by Nippon Aerosil Co., Ltd.), 1.25% by weight of acetylacetone, and 1.88% by weight of polyethylene glycol (with an average molecular weight of 3000) were dispersed or dissolved in water and isopropyl alcohol to form a slurry. The slurry was applied to the substrate having the intermediate layer-forming layer with a doctor blade and then allowed to stand at room temperature for 20 minutes and dried at 100° C. for 30 minutes. Thereafter, the substrate was sintered at 500° C. under atmospheric pressure for 30 minutes in an electric muffle furnace (P90 manufactured by Denken Co., Ltd.) so that a porous intermediate membrane and a porous oxide semiconductor membrane were formed. After the sintering, it was determined by photoelectron spectroscopy that no acrylic resin remained in the intermediate membrane and that no polyethylene glycol remained in the oxide semiconductor membrane. Thus, it was possible to thermally decompose and eliminate the acrylic resin and the polyethylene glycol by sintering. The intermediate membrane and the oxide semiconductor membrane were well formed on the glass substrate without peeling in this process.

Preparation of First Electrode Layer

After the intermediate membrane and the oxide semiconductor membrane were formed on the substrate, an ITO film with a thickness of 200 nm was formed thereon by an ion plating method. The resulting ITO film had a surface electrical resistance of 10 Ω/square.

Transfer Process

After the ITO film (the first electrode layer) was formed, a heat-sealable Surlyn (registered trademark) film comprising an ionomer resin (with a thickness of 50 μm, manufactured by Du Pont K. K.) was layered on a polyethylene terephthalate film (with a thickness of 100 μm, A4300 manufactured by Toyobo Co., Ltd.) provided as a substrate, and the substrate having the ITO film, the oxide semiconductor membrane and the intermediate membrane was then placed thereon. Thereafter, they were press-bonded at 120° C. for 20 minutes with a vacuum laminator so that the ITO film, the intermediate membrane and the oxide semiconductor membrane were formed on the polyethylene terephthalate film substrate. The intermediate membrane and the oxide semiconductor membrane were then trimmed into 1 cm×1 cm size.

Preparation of Solution of Dye to be Adsorbed

A dye sensitizer of a ruthenium complex (RuL₂(NCS)₂, KOJIMA-Chemical) was dissolved at a concentration of 3×10⁻⁴ mol/l in absolute ethanol to form a solution of the dye sensitizer to be adsorbed.

Dye Adsorption

The substrate having the intermediate membrane and the oxide semiconductor membrane was dipped in the dye solution and allowed to stand under stirring at 40° C. for 3 hours, so that a dye-sensitized solar cell substrate having an intermediate layer (the dye-adsorbed intermediate membrane) and an oxide semiconductor layer (the dye-adsorbed oxide semiconductor membrane) was produced.

Electrolyte Preparation

An electrolyte layer-forming coating material was prepared as follows. In a solvent of methoxyacetonitrile were dissolved 0.1 mol/l of lithium iodide, 0.05 mol/l of iodine, 0.3 mol/l of dimethylpropyl imidazolium iodide, and 0.5 mol/l of tert-butyl pyridine to form a liquid electrolyte.

Preparation of Device

The film substrate having the oxide semiconductor layer was bonded to a counter substrate with a 20 μm-thick Surlyn (registered trademark) film, and the electrolyte layer-forming coating material was injected between them, so that a device was prepared. The counter substrate used was composed of a counter film substrate having a sputtered ITO layer with a thickness of 150 nm and a surface electrical resistance of 7 Ω/square and a 50 nm-thick platinum film formed on the film substrate by sputtering.

Performance Evaluation

The prepared device was evaluated as follows. In an AM1.5 solar simulator (with an incident light intensity of 100 mW/cm²), the side of the substrate having the dye-adsorbed oxide semiconductor layer was exposed to light, when current-voltage characteristics were measured under the application of voltages with a source-measure unit (Keithley 2400 type). As a result, the device had a short-circuit current of 13.3 mA/cm², an open-circuit voltage of 660 mV and a conversion efficiency of 4.9%.

### Example 1-2

A dye-sensitized solar cell was prepared using the process of Example 1-1 except that an acrylic resin comprising poly (ethyl methacrylate) as a main component (with a molecular weight of 180000 and a glass transition temperature of 20° C.) (BR112 manufactured by Mitsubishi Rayon Co., Ltd.) was used in place of the acrylic resin BR87 in the process of forming the intermediate layer-forming layer.

As a result, the dye-sensitized solar cell had a short-circuit current of 12.8 mA/cm², an open-circuit voltage of 660 mV and a conversion efficiency of 4.8%.

### Example 1-3

A dye-sensitized solar cell was prepared using the process of Example 1-1 except that an acrylic resin comprising a tert-butyl methacrylate/n-butyl methacrylate/isobutyl methacrylate copolymer as a main component (with a molecular weight of 230000 and a glass transition temperature of 230° C.) (BR90 manufactured by Mitsubishi Rayon Co., Ltd.) was used in place of the acrylic resin BR87 in the process of forming the intermediate layer-forming layer.

As a result, the dye-sensitized solar cell had a short-circuit current of 11.8 mA/cm², an open-circuit voltage of 670 mV and a conversion efficiency of 4.6%.

### Example 1-4

A dye-sensitized solar cell was prepared using the process of Example 1-1 except that the content of P25 and the content of the acrylic resin BR87 were each set at 5% by weight when the coating material was prepared in the process of forming the intermediate layer-forming layer.

As a result, the dye-sensitized solar cell had a short-circuit current of 13.5 mA/cm², an open-circuit voltage of 670 mV and a conversion efficiency of 5.2%.

### Example 1-5

A dye-sensitized solar cell was prepared using the process of Example 1-1 except that the content of P25 and the content of the acrylic resin BR87 were each set at 9.1% by weight when the coating material was prepared in the process of forming the intermediate layer-forming layer.

As a result, the dye-sensitized solar cell had a short-circuit current of 13.2 mA/cm², an open-circuit voltage of 660 mV and a conversion efficiency of 4.9%.

### Example 1-6

A dye-sensitized solar cell was prepared using the process of Example 1-1 except that the first electrode layer was formed by the method as described below.

Preparation of First Electrode Layer

After the intermediate membrane and the oxide semiconductor membrane were formed on the substrate, a first electrode undercoat layer-forming coating material was prepared by dissolving 0.01 mol/l of indium nitrate, 0.005 mol/l of tin chloride, and 0.2 mol/l of borane-dimethylamine complex (DMAB) in purified water. The substrate having the oxide semiconductor membrane and the intermediate membrane was dipped in the coating material for 1 minute. Thereafter, the substrate was sintered at 350° C. for 30 minutes in the furnace.

A first electrode upper layer-forming coating material was then prepared by dissolving 0.1 mol/l of indium chloride and 0.005 mol/l of tin chloride in ethanol. After the above sintering, the substrate was placed on a hot plate (400° C.) with the oxide semiconductor membrane facing upward, and the first electrode upper layer-forming coating material was sprayed on the heated oxide semiconductor membrane from an ultrasonic atomizer so that an ITO film (the first electrode layer) was formed.

The resulting device was evaluated for its performance. As a result, it had a short-circuit current of 15.8 mA/cm², an open-circuit voltage of 690 mV and a conversion efficiency of 5.5%.

### Example 1-7

A dye-sensitized solar cell was prepared using the process of Example 1-1 except that the first electrode layer was formed by the method as described below.

Preparation of First Electrode Layer

After the intermediate membrane and the oxide semiconductor membrane were formed on the substrate, a first electrode layer-forming coating material was prepared by dissolving 0.1 mol/l of indium chloride and 0.005 mol/l of tin chloride in ethanol. Thereafter, the substrate was placed on a hot plate (400° C.) with the oxide semiconductor membrane facing upward, and the first electrode layer-forming coating material was sprayed on the heated oxide semiconductor membrane from an ultrasonic atomizer so that an ITO film (the first electrode layer) was formed.

The resulting device was evaluated for its performance. As a result, it had a short-circuit current of 14.2 mA/cm², an open-circuit voltage of 680 mV and a conversion efficiency of 5.2%.

### Comparative Example 1-1

The process of Example 1-1 was used for the preparation of a dye-sensitized solar cell except that no intermediate layer was formed.

In this case, the alkali-free glass substrate provided as a heat-resistant substrate and the oxide semiconductor membrane were strongly bonded to each other so that it was impossible to transfer the oxide semiconductor membrane to the film substrate with the heat-sealable resin.

### Comparative Example 1-2

The process of Example 1-1 was used for the preparation of a dye-sensitized solar cell except that no resin was used for the formation of the intermediate layer.

When the intermediate layer-forming coating material was applied, no membrane was formed, and the coating showed no adhesiveness to the alkali-free glass substrate (provided as a heat-resistant substrate), so that it was impossible to prepare any cell.

### Comparative Example 1-3

The process of Example 1-1 was used for the preparation of a dye-sensitized solar cell except that TiO₂ was not used for the formation of the intermediate layer and that the content of BR87 was 9.1% by weight when the intermediate layer-forming layer was formed using the intermediate layer-forming coating material.

In this case, the oxide semiconductor membrane was not bonded to the alkali-free glass substrate (provided as a heat-resistant substrate) after the sintering so that it was impossible to perform the next step.

### Comparative Example 1-4

The process of Example 1-2 was used for the preparation of a dye-sensitized solar cell except that TiO₂ was not used for the formation of the intermediate layer and that the content of BR112 was 9.1% by weight when the intermediate layer-forming layer was formed using the intermediate layer-forming coating material.

In this case, the oxide semiconductor membrane was not bonded to the alkali-free glass substrate (provided as a heat-resistant substrate) after the sintering so that it was impossible to perform the next step.

### Comparative Example 1-5

The process of Example 1-3 was used for the preparation of a dye-sensitized solar cell except that TiO₂ was not used for the formation of the intermediate layer and that the content of BR90 was 9.1% by weight when the intermediate layer-forming layer was formed using the intermediate layer-forming coating material.

In this case, the oxide semiconductor membrane was not bonded to the alkali-free glass substrate (provided as a heat-resistant substrate) after the sintering so that it was impossible to perform the next step.

### Example 2-1

### Preparation of Electrically-Conductive Substrate and Electrode Substrate for Dye-Sensitized Solar Cell

(1) Preparation of Transfer Member

A 1 mm-thick blue plate glass was provided as a heat-resistant substrate. A first oxide semiconductor layer-forming coating material (coating material A) and a second oxide semiconductor layer-forming coating material (coating material B) were prepared, respectively.

Coating material A was a dispersion of fine titanium oxide particles with a primary particle diameter of 20 nm (P-25 (trade name) manufactured by Nippon Aerosil Co., Ltd.) in a solution prepared by dissolving an organic binder of an acrylic resin (BR87 (trade name) manufactured by Mitsubishi Rayon Co., Ltd. with a molecular weight of 25000 and a glass transition temperature of 105° C.) in a solvent mixture of 1:1 (weight ratio) of methyl ethyl ketone and toluene. In coating material A, the content of the acrylic resin was 9.09 wt % and that of the fine titanium oxide particles was 5 wt %.

Coating material B was a dispersion of fine titanium oxide particles with a primary particle diameter of 20 nm (P-25 (trade name) manufactured by Nippon Aerosil Co., Ltd.) in a solution prepared by dissolving a surfactant and an organic binder of polyethylene glycol (with a number average molecular weight of 20000) in a solvent mixture of acetylacetone and ion-exchanged water. In coating material B, the contents of the polyethylene glycol, the fine titanium oxide particles, the acetylacetone, and the surfactant were 1.88 wt %, 37.5 wt %, 1.25 wt %, and 1.25 wt %, respectively.

Coating material A was applied to the blue plate glass with a wire bar in an amount of 1.5 g/m² to form a coating film (named coating film A), which was then dried. After the drying, coating material B was applied to coating film A with a doctor blade in an amount of 15 g/m² to form a coating film (named coating film B), which was allowed to stand at room temperature for 20 minutes and then dried by heating at 100° C. for 30 minutes.

The blue plate glass having coating films A and B was placed in an electric muffle furnace (P90 manufactured by Denken Co., Ltd.) and sintered in air atmosphere at 550° C. for 30 minutes (holding time at 550° C.) so that an oxide semiconductor layer (a porous titanium oxide layer) comprising: a first oxide semiconductor layer (a first porous titanium oxide layer) as a sintered product from coating film A; and a second oxide semiconductor layer (a second porous titanium oxide layer) formed thereon as a sintered product from coating film B was formed on the blue plate glass. In this process, local peeling was not observed in the oxide semiconductor layer (porous titanium oxide layer).

Thereafter, while the blue plate glass having the oxide semiconductor layer was heated at 350° C., an ITO film with an average thickness of 0.5 μm was formed on the oxide semiconductor layer by a spray method so that a transfer member for use in forming an oxide semiconductor layer was obtained. In the process of forming the ITO film by the spray method, 50 ml of a solution of 0.1 mol/l indium trichloride hydrate (InCl₃.3H₂O) and 0.0052 mol/l stannous chloride hydrate (SnCl₂.2H₂O) in ethanol was continuously sprayed on the oxide semiconductor layer from an ultrasonic atomizer.

(2) Preparation of Electrically-Conductive Substrate

A polyethylene terephthalate film having a 0.3 μm-thick ITO film on its one side (125 μm in thickness, manufactured by Tobi Co., Ltd.) was provided. A coating material for forming an electrically-conductive transparent organic-inorganic composite layer was prepared by dispersing or dissolving fine ITO particles with an average size of 20 nm (manufactured by Sumitomo Metal Mining Co., Ltd.) and an organic solvent-soluble polyester resin (Vylon 500 (trade name) with a glass transition temperature of 4° C. manufactured by Toyobo Co., Ltd.) in a solvent mixture of 1:1 (weight ratio) of methyl ethyl ketone and toluene. In this coating material, the content of the fine ITO particles was 29 wt %, and that of the organic solvent-soluble polyester resin was 20 wt %.

The coating material was then applied with a wire bar to the ITO film formed on the polyethylene terephthalate film to form a coating film, which was dried at 100° C. for 5 minutes, so that a 1 μm-thick, heat-sealable, electrically-conductive, transparent, organic-inorganic composite layer was formed. The plan view size of the electrically-conductive transparent organic-inorganic composite layer was 5 cm×10 cm, and the ITO film was exposed at the peripheral of the electrically-conductive transparent organic-inorganic composite layer.

The polyethylene terephthalate film also having the electrically-conductive transparent organic-inorganic composite layer and the transfer member prepared in the section (1) were arranged in such a manner that the electrically-conductive transparent organic-inorganic composite layer and the ITO film of the transfer member were opposed to each other, and they were fed to a roller laminator, so that they were bonded together by heating at 150° C. and pressing for 1 minute in the roller laminator. Thereafter, the blue plate glass as a component of the transfer member was peeled off by hand so that an electrically-conductive substrate having the oxide semiconductor layer (the porous titanium oxide layer) was obtained. In this electrically-conductive substrate, the plan view size of the oxide semiconductor layer (the porous titanium oxide layer) was 5 cm×10 cm. The ITO film previously formed on the polyethylene terephthalate film corresponds to the electrically-conductive transparent inorganic layer, and the ITO film transferred onto the electrically-conductive transparent organic-inorganic composite layer corresponds to the first electrode layer.

Chemical composition analysis was performed on the surface of the oxide semiconductor layer of the resulting electrically-conductive substrate by X-ray photoelectron spectroscopy. As a result, a residue of the acrylic resin used as an organic binder for coating material A was not detected. After the peeling, chemical composition analysis was also performed on the surface of the blue plate glass (the surface on which the oxide semiconductor layer had been formed) by X-ray photoelectron spectroscopy. As a result, no titanium oxide-derived component was detected. Thus, it has been found that there is very little residue of fine titanium oxide particles on the blue plate glass. Therefore, it has been determined that the oxide semiconductor layer (the porous titanium oxide layer) having a two-layer structure has been uniformly transferred together with the ITO film onto the electrically-conductive transparent organic-inorganic composite layer.

(3) Preparation of Electrode Substrate for Dye-Sensitized Solar Cell

A sensitizing dye of a ruthenium complex (manufactured by KOJIMA-Chemical) was dissolved at a concentration of 3×10⁻⁴ mol/l in ethanol to form a dye solution. The electrically-conductive substrate prepared in the section (2) was dipped in the dye solution and allowed to stand at a liquid temperature of 40° C. for 1 hour while the dye solution was stirred, and then the electrically-conductive substrate was pulled out of the dye solution and air-dried, so that the dye was fixed on the oxide semiconductor layer and that an electrode substrate for a dye-sensitized solar cell was obtained.

### Example 2-2

### Preparation of Electrically-Conductive Substrate and Electrode Substrate for Dye-Sensitized Solar Cell

A transfer member was prepared using the conditions of Example 2-1 (1) except that concerning coating material A, the content of the fine titanium oxide particles was changed to 9.09 wt %, while that of the acrylic resin was kept at 9.09 wt %. An electrically-conductive substrate was prepared using the conditions of Example 2-1 (2) except that the resulting transfer member was used. In this electrically-conductive substrate, the two-layered oxide semiconductor layer (the porous titanium oxide layer) was also uniformly transferred together with the ITO film on the electrically-conductive transparent organic-inorganic composite layer as in the case of the electrically-conductive substrate prepared in Example 2-1. An electrode substrate for a dye-sensitized solar cell was then prepared using the conditions of Example 2-1 (3) except that the resulting electrically-conductive substrate was used.

### Example 2-3

### Preparation of Electrically-Conductive Substrate and Electrode Substrate for Dye-Sensitized Solar Cell

A transfer member was prepared using the conditions of Example 2-2 except that Ti Nanoxide D (trade name) manufactured by Solaronix SA was used as coating material B, and an electrically-conductive substrate was prepared using the conditions of Example 2-2 except that the resulting transfer member was used. Ti Nanoxide D contains 10.7 wt % of fine titanium oxide particles with an average particle diameter of 13 nm together with such other components as an organic binder and an organic solvent.

Concerning this electrically-conductive substrate, a residue of the oxide semiconductor layer (porous titanium oxide layer) was detected on the surface of the blue plate glass after the transfer and peeling process. On the other hand, it has been determined that the oxide semiconductor layer (porous titanium oxide layer) is formed on the electrically-conductive transparent organic-inorganic composite layer via the ITO film. The residue of the porous titanium oxide layer on the surface of the blue plate glass was measured for average thickness. As a result, the average thickness of the residue was substantially equal to that of the part produced from coating material A in the porous titanium oxide layer of the transfer member. From the result, it can be concluded that the porous titanium oxide monolayer produced from coating material B should be transferred together with the ITO film onto the electrically-conductive transparent organic-inorganic composite layer.

An electrode substrate for a dye-sensitized solar cell was prepared using the conditions of Example 2-1 (3) except that the resulting electrically-conductive substrate was used.

### Example 2-4

### Preparation of Electrically-Conductive Substrate and Electrode Substrate for Dye-Sensitized Solar Cell

A transfer member was prepared using the conditions of Example 2-3 except that concerning coating material A, the content of the fine titanium oxide particles was changed to 7 wt %, while that of the acrylic resin was kept at 9.09 wt %. An electrically-conductive substrate was prepared using the conditions of Example 2-3 except that the resulting transfer member was used. In the electrically-conductive substrate, the oxide semiconductor monolayer (porous titanium oxide layer) produced from coating material B was also uniformly transferred together with the ITO film on the electrically-conductive transparent organic-inorganic composite layer as in the case of the electrically-conductive substrate prepared in Example 2-3. An electrode substrate for a dye-sensitized solar cell was then prepared using the conditions of Example 2-1 (3) except that the resulting electrically-conductive substrate was used.

### Example 2-5

### Preparation of Electrically-Conductive Substrate and Electrode Substrate for Dye-Sensitized Solar Cell

An organic binder of an acrylic resin (BR87 (trade name) manufactured by Mitsubishi Rayon Co., Ltd. with a molecular weight of 25000 and a glass transition temperature of 105° C.) was dissolved in acetone to form a solution. Ti Nanoxide D (trade name) manufactured by Solaronix SA was added to the resulting solution and mixed to form a coating material (named coating material A) for use in forming a transfer member. In coating material A, the content of the acrylic resin was 9.09 wt %, and that of the fine titanium oxide particles was 1.5 wt %.

A transfer member was prepared using the conditions of Example 2-3 except that the resulting coating material A was used. An electrically-conductive substrate was prepared using the conditions of Example 2-3 except that the resulting transfer member was used. In the electrically-conductive substrate, the oxide semiconductor monolayer (porous titanium oxide layer) produced from coating material B was also uniformly transferred together with the ITO film on the electrically-conductive transparent organic-inorganic composite layer as in the case of the electrically-conductive substrate prepared in Example 2-3.

An electrode substrate for a dye-sensitized solar cell was then prepared using the conditions of Example 2-1 (3) except that the resulting electrically-conductive substrate was used.

### Examples 2-6 and 2-7

### Preparation of Electrically-Conductive Substrate and Electrode Substrate for Dye-Sensitized Solar Cell

In each example, a transfer member was prepared using the conditions of Example 2-5 except that concerning coating material A, the content of the fine titanium oxide particles was changed to 1 wt % (Example 2-6) or 2 wt % (Example 2-7), while that of the acrylic resin was kept at 9.09 wt %. In each example, an electrically-conductive substrate was prepared using the conditions of Example 2-5 except that the resulting transfer member was used. In each electrically-conductive substrate, the oxide semiconductor monolayer (the titanium oxide layer) produced from coating material B was also uniformly transferred together with the ITO film on the electrically-conductive transparent organic-inorganic composite layer as in the case of the electrically-conductive substrate prepared in Example 2-5. In each example, an electrode substrate for a dye-sensitized solar cell was then prepared using the conditions of Example 2-1 (3) except that the resulting electrically-conductive substrate was used.

### Example 2-8

### Preparation of Electrically-Conductive Substrate and Electrode Substrate for Dye-Sensitized Solar Cell

A polyethylene terephthalate film having a 0.3 μm-thick ITO film on its one side (125 μm in thickness, manufactured by Tobi Co., Ltd.) was prepared. A coating material for forming an electrically-conductive transparent organic-inorganic composite layer was prepared by dispersing or dissolving fine ITO particles with an average particle diameter of 20 nm (manufactured by Sumitomo Metal Mining Co., Ltd.) and an organic solvent-soluble polyester resin (Vylon 500 (trade name) with a glass transition temperature of 4° C. manufactured by Toyobo Co., Ltd.) in a solvent mixture of 1:1 (weight ratio) of methyl ethyl ketone and toluene. In this coating material, the content of the fine ITO particles was 21 wt %, and that of the organic solvent-soluble polyester resin was 5.3 wt %.

The coating material was then applied in an amount of 0.5 g/m² with a wire bar to the ITO film formed on the polyethylene terephthalate film to form a coating film, which was dried at 100° C. for 10 minutes to form an electrically-conductive transparent organic-inorganic composite layer with a thickness of 0.8 μm. The plan-view size of the electrically-conductive transparent organic-inorganic composite layer was 5 cm×10 cm, and the ITO film was exposed at the peripheral of the electrically-conductive transparent organic-inorganic composite layer.

A 0.5 μm-thick ITO film was formed on the electrically-conductive transparent organic-inorganic composite layer by a sputtering method. Fine titanium oxide particles with a primary particle diameter of 20 nm (F-5 (trade name) manufactured by SHOWA DENKO K. K.) were dispersed in a solvent mixture of 1:1 (weight ratio) of water and tert-butanol to form a paste. The resulting paste was applied with a wire bar to the electrically-conductive transparent organic-inorganic composite layer to form a coating film, which was heat-treated at 150° C. for 30 minutes so that a 12 μm-thick oxide semiconductor monolayer (porous titanium oxide layer) was formed.

An electrically-conductive substrate was obtained when the oxide semiconductor layer was formed. In the electrically-conductive substrate, the ITO film previously formed on the polyethylene terephthalate film corresponds to the electrically-conductive transparent inorganic layer, and the ITO film formed on the electrically-conductive transparent organic-inorganic composite layer by the sputtering method corresponds to the first electrode layer. An electrode substrate for a dye-sensitized solar cell was then prepared using the conditions of Example 2-1 (3) except that the resulting electrically-conductive substrate was used.

### Example 2-9

### Preparation of Electrically-Conductive Substrate and Electrode Substrate for Dye-Sensitized Solar Cell

A polyethylene terephthalate film having a 0.3 μm-thick ITO film on its one side (125 μm in thickness, manufactured by Tobi Co., Ltd.) was prepared. A coating material for forming an electrically-conductive transparent organic-inorganic composite layer was prepared by dispersing or dissolving 15 wt % of fine ITO particles with an average particle diameter of 20 nm (manufactured by Sumitomo Metal Mining Co., Ltd.), 6 wt % of a polyester adhesive (DIC Seal A-970 (trade name) manufactured by Dainippon Ink and Chemicals, Incorporated) and 0.5 wt % of an isocyanate type curing agent (KX-75 (trade name) manufactured by Dainippon Ink and Chemicals, Incorporated) in a solvent mixture of 1:1 (weight ratio) of methyl ethyl ketone and toluene.

The coating material was then applied in an amount of 0.5 g/m² with a wire bar to the ITO film formed on the polyethylene terephthalate film to form a coating film, which was dried at 100° C. for 10 minutes to form a 0.8 μm-thick uncured-state layer, which would be converted into an electrically-conductive transparent organic-inorganic composite layer. The plan view size of the uncured-state layer was 5 cm×10 cm, and the ITO film was exposed at the peripheral of the uncured-state layer. An ITO film and an oxide semiconductor layer (porous titanium oxide layer) were then sequentially formed on the uncured-state layer using the conditions of Example 2-8.

After the oxide semiconductor layer (porous titanium oxide layer) was formed, the uncured-state layer was cured at 40° C. for 5 days so that an electrically-conductive substrate was obtained. In the electrically-conductive substrate, the ITO film previously formed on the polyethylene terephthalate film corresponds to the electrically-conductive transparent inorganic layer, and the ITO film formed on the uncured-state layer by the sputtering method corresponds to the first electrode layer.

An electrode substrate for a dye-sensitized solar cell was then prepared using the conditions of Example 2-1 (3) except that the resulting electrically-conductive substrate was used.

### Example 2-10

### Preparation of Transfer Member

An organic binder of polyethylene glycol (with a number average molecular weight of 3000) was dissolved at a concentration of 10 wt % in a solvent mixture of 1:1 (weight ratio) of purified water and ethanol to form a solution. Ti Nanoxide D (trade name) manufactured by Solaronix SA was added to the resulting solution and mixed to form a coating material (named coating material A) for use in forming a transfer member. The content of the fine titanium oxide particles in coating material A was 1.5 wt %.

A transfer member was prepared using the conditions of Example 2-3 except that the resulting coating material A was used. The resulting transfer member was subjected to the following tape peel test.

An about 5 cm cut of an adhesive cellophane tape (Cellotape CT-12M (trade name) manufactured by Nichiban Co., Ltd.) was attached to 4 cm part of the oxide semiconductor layer (porous titanium oxide layer) of the transfer member and then bonded to it by rubbing the surface of the tape by fingers. Thereafter, the cellophane tape was slowly peeled off by pulling its unbonded end, when the presence or absence of any porous oxide semiconductor layer peeled with the cellophane tape and the presence or absence of any residue of the oxide semiconductor layer (porous titanium oxide layer) at the cellophane tape-peeled portion of the heat-resistant substrate (the blue plate glass) were visually determined.

As a result, it has been observed that the oxide semiconductor layer (porous titanium oxide layer) adheres to the cellophane tape and that there is no residue of the oxide semiconductor layer (porous titanium oxide layer) at the cellophane tape-peeled portion of the blue plate glass. Chemical composition analysis was performed on the surface of the cellophane tape-peeled portion of the blue plate glass. As a result, no titanium oxide-derived component was detected. Thus, it has been concluded that there is very little residue of fine titanium oxide particles on the blue plate glass. Therefore, it has been concluded that the oxide semiconductor layer (the porous titanium oxide layer) having a two-layer structure has been uniformly bonded to the cellophane tape.

### Examples 2-11 and 2-12

### Preparation of Transfer Member

In each example, coating material A was prepared under the conditions of Example 2-10 except that polyethylene glycol with a number average molecular weight of 8300 or 20000 was used, and a transfer member was prepared using the conditions of Example 2-3 except that the resulting coating material A was used. Each resulting transfer member was subjected to a tape peel test under the conditions of Example 2-10.

As a result, it has been observed that the oxide semiconductor layer (porous titanium oxide layer) adheres to the cellophane tape with respect to the transfer member of each example and that there is no residue of the oxide semiconductor layer (porous titanium oxide layer) at the cellophane tape-peeled portion of the blue plate glass. Chemical composition analysis was performed on the surface of the cellophane tape-peeled portion of the blue plate glass. In each example, the same result as in Example 2-10 was obtained. Thus, it has been concluded that the oxide semiconductor layer (the porous titanium oxide layer) having a two-layer structure has been uniformly bonded to the cellophane tape with respect to the transfer member of each example.

### Example 2-13

### Preparation of Dye-Sensitized Solar Cell

A polyethylene terephthalate film having a 0.3 μm-thick ITO film on its one side (188 μm in thickness, manufactured by Tobi Co., Ltd.) was provided. A thin platinum film with a thickness of 50 nm was formed on the ITO film of the polyethylene terephthalate film by a sputtering method so that an electrode substrate for use as a counter electrode part in a dye-sensitized solar cell (hereinafter referred to as “the counter electrode substrate”) was obtained.

The electrode substrate produced in Example 2-1 (3) for a dye-sensitized solar cell was trimmed such that the plan-view size of the oxide semiconductor layer (titanium oxide layer) was 1 cm×1 cm and that the ITO film previously formed on the polyethylene terephthalate film partially projected from the plane visually defined by the oxide semiconductor layer (titanium oxide layer). Hereinafter, the trimmed product is referred to as “the dye-sensitized solar cell substrate.” The dye-sensitized solar cell substrate and the counter electrode substrate were bonded together using a 20 μm-thick heat-sealable film (Surlyn (trade name) manufactured by Du Pont K. K.), and the space between the dye-sensitized solar cell substrate and the counter electrode substrate was filled with a liquid electrolyte so that an electrolyte layer was formed.

Before use, the heat-sealable film was shaped into a rectangular frame such that it would be bonded to only an inner periphery of each of the dye-sensitized solar cell substrate and the counter electrode substrate. The liquid electrolyte was a solution of 0.1 mol/l lithium iodide, 0.05 mol/l iodine, 0.3 mol/l dimethylpropyl imidazolium iodide, and 0.5 mol/l tert-butyl pyridine in a solvent of methoxyacetonitrile.

Thereafter, a lead electrode was connected to the ITO film of the dye-sensitized solar cell substrate (the ITO film previously formed on the polyethylene terephthalate film) and to the ITO film of the counter electrode substrate, respectively. The two ITO films were connected to an outer load via the lead electrodes so that a dye-sensitized solar cell was prepared.

### Examples 2-14 to 2-21

### Preparation of Dye-Sensitized Solar Cells

Eight types of dye-sensitized solar cells using different dye-sensitized solar cell substrates were prepared using the conditions of Example 2-13 except that each of the electrode substrates for dye-sensitized solar cells prepared in Examples 2-9 was used.

### Comparative Example 2-1

An electrically-conductive substrate was prepared using the conditions of the Example 2-8 except that the process of forming the electrically-conductive transparent organic-inorganic composite layer and the process of forming the ITO film on the electrically-conductive transparent organic-inorganic composite layer were omitted. In this electrically-conductive substrate, the oxide semiconductor layer (porous titanium oxide layer) was formed by the coating method directly on the ITO film previously formed on a side of the polyethylene terephthalate. An electrode substrate for a dye-sensitized solar cell was prepared using the conditions of Example 2-1 (3) except that the resulting electrically-conductive substrate was used. A dye-sensitized solar cell was also prepared using the conditions of Example 2-13 except that the resulting electrode substrate was used.

### Comparative Examples 2-2 and 2-3

The conditions of Example 2-1 (1) were used for preparation of a transfer member except that with respect to coating material A, the content of the fine titanium oxide particles was changed to 0 wt % (Comparative Example 2-2) or 1 wt % (Comparative Example 2-3), while that of the acrylic resin was not changed. In each of Examples 2-2 and 2-3, the oxide semiconductor layer (porous titanium oxide layer) was released from the blue plate glass so that it was impossible to perform the next process of forming the ITO film.

### Comparative Examples 2-4 and 2-5

A transfer member was prepared using the conditions of Example 2-1 (1) or 2-3 except that coating material A was not used. The conditions of Example 2-1 (2) or 2-3 were used for preparation of an ITO film and an oxide semiconductor layer (porous titanium oxide layer) on the electrically-conductive transparent organic-inorganic composite layer, except that the resulting transfer member was used. However, the oxide semiconductor layer (porous titanium oxide layer) and the blue plate glass of the transfer member were strongly bonded together so that it was impossible to peel off the blue plate glass after the heat-press bonding with the roller laminator.

### Comparative Examples 2-6 and 2-7

The conditions of Example 2-3 were used for preparation of a transfer member except that with respect to coating material A, the content of the fine titanium oxide particles was changed to 1 wt % (Comparative Example 2-6) or 5 wt % (Comparative Example 2-7), while that of the acrylic resin was not changed. In each of Examples 2-6 and 2-7, the oxide semiconductor layer (porous titanium oxide layer) flaked off from the blue plate glass during the sintering process so that it was impossible to perform the next process of forming the ITO film.

### Comparative Examples 2-8 to 2-10

The conditions of Example 2-5 were used for preparation of a transfer member except that with respect to coating material A, the content of the fine titanium oxide particles was changed to 2.5 wt % (Comparative Example 2-8), 3 wt % (Comparative Example 2-9) or 3.5 wt % (Comparative Example 2-10), while that of the acrylic resin was not changed. The process of forming a transfer member was broken off after the oxide semiconductor layer (porous titanium oxide layer) was formed, and then a tape peel test was performed on the oxide semiconductor layer (porous titanium oxide layer) under the conditions of Example 2-10.

As a result, in each of Comparative Examples 2-8 to 2-10, the oxide semiconductor layer (porous titanium oxide layer) adhered to the cellophane tape. Even by visual observation, it was apparent that the oxide semiconductor layer (porous titanium oxide layer) adhering to the cellophane tape was thinner than the oxide semiconductor layer (porous titanium oxide layer) derived from coating material B. This suggests that cohesive failure should occur in the oxide semiconductor layer (porous titanium oxide layer) produced from coating material B during the process of peeling off the cellophane tape. It can be judged that a transfer member having such an oxide semiconductor layer (porous titanium oxide layer) cannot form an oxide semiconductor layer of substantially uniform thickness.

### Comparative Example 2-11

The conditions of Example 2-1 (2) were used for preparation of an electrically-conductive substrate except that with respect to the coating material for forming the electrically-conductive transparent organic-inorganic composite layer, the content of the fine ITO particles was changed to 55 wt %, while that of the organic solvent-soluble polyester resin was kept at 20 wt %. The resulting electrically-conductive transparent organic-inorganic composite layer had no heat-sealability so that it was impossible to transfer the ITO film and the oxide semiconductor layer (porous titanium oxide layer).

Evaluation 1

Ten types of electrically-conductive substrates were prepared using the conditions of Examples 2-1 to 2-9 and Comparative Example 2-1, respectively. Each of these electrically-conductive substrates (hereinafter also generically referred to as “the sample”) was subjected to a bending test (a cylindrical mandrel method) according to JIS K5600-5-1 for the purpose of evaluating the flexibility of the oxide semiconductor layer (porous titanium oxide layer) to bending deformation.

Specifically, a mandrel 5 mm in diameter (type 1 made of stainless steel) was used, and the sample was placed on it with the oxide semiconductor layer (porous titanium oxide layer) placed outside. After 100 cycles of 180° bending by 2 seconds were performed, the oxide semiconductor layer (porous titanium oxide layer) was visually observed for determination of the presence or absence of peeling.

As a result, no peeling was observed in each of the electrically-conductive substrates prepared under the conditions of Examples 2-1 to 2-9, and it has been demonstrated that the electrically-conductive substrates have high flexibility to bending deformation. In contrast, some peeling occurred in the oxide semiconductor layer (porous titanium oxide layer) of the electrically-conductive substrate prepared under the conditions of Comparative Example 1, when 10 cycles of the bending were performed.

Evaluation 2

Current-voltage characteristics were measured with respect to the dye-sensitized solar cells prepared in Examples 2-13 to 2-21 and Comparative Example 2-1, respectively, and with respect to the dye-sensitized solar cells which were prepared under the conditions of Examples 2-13 to 2-21, respectively, except that the electrically-conductive substrate was used after the bending test was performed according to Evaluation 1. In a solar simulator (AM1.5 with an incident light intensity of 100 mW/cm²), the side of the dye-sensitized solar cell substrate was exposed to simulated solar radiation, when current-voltage characteristics were measured under the application of voltages with a source-measure unit (Keithley 2400 type). No dye-sensitized solar cell was produced with the electrically-conductive substrate prepared under the conditions of Comparative Example 2-1, because the oxide semiconductor layer (porous titanium oxide layer) peeled off from the substrate in the bending test according to Evaluation 1.

Table 1 shows the results of measurement of the current-voltage characteristics. In Table 1, the current-voltage characteristics of the dye-sensitized solar cell prepared in Example 2-13 are shown in the row entitled “Example 2-13 No Bending Test,” and the current-voltage characteristics of the dye-sensitized solar cells which was prepared under the conditions of Examples 2-13, except that the electrically-conductive substrate was used after the bending test was performed are shown in the row entitled “Example 2-13 After Bending Test.” The current-voltage characteristics of the other dye-sensitized solar cells are also shown in the same manner.

TABLE 1

| | Type of | | Current-Voltage Characteristics | | |
|---|---|---|---|---|---|
| | Electrically-Conductive | | Short-Circuit | Open-Circuit | Conversion |
| | Substrate for First Electrode | | Current | Voltage | Efficiency |
| | Substrate | | (mA/cm²) | (mV) | (%) |
| Example 2-13 | Prepared in | No Bending | 9.02 | 702 | 3.80 |
| | Example 2-1 | Test | | | |
| | | After Bending | 8.96 | 700 | 3.76 |
| | | Test | | | |
| Example 2-14 | Prepared in | No Bending | 8.92 | 703 | 3.76 |
| | Example 2-2 | Test | | | |
| | | After Bending | 8.85 | 698 | 3.71 |
| | | Test | | | |
| Example 2-15 | Prepared in | No Bending | 11.25 | 726 | 4.90 |
| | Example 2-3 | Test | | | |
| | | After Bending | 11.18 | 713 | 4.78 |
| | | Test | | | |
| Example 2-16 | Prepared in | No Bending | 11.30 | 715 | 4.84 |
| | Example 2-4 | Test | | | |
| | | After Bending | 11.24 | 709 | 4.82 |
| | | Test | | | |
| Example 2-17 | Prepared in | No Bending | 11.16 | 710 | 4.75 |
| | Example 2-5 | Test | | | |
| | | After Bending | 11.14 | 706 | 4.72 |
| | | Test | | | |
| Example 2-18 | Prepared in | No Bending | 11.25 | 705 | 4.76 |
| | Example 2-6 | Test | | | |
| | | After Bending | 11.13 | 705 | 4.71 |
| | | Test | | | |
| Example 2-19 | Prepared in | No Bending | 11.26 | 712 | 4.81 |
| | Example 2-7 | Test | | | |
| | | After Bending | 11.20 | 708 | 4.76 |
| | | Test | | | |
| Example 2-20 | Prepared in | No Bending | 7.41 | 695 | 3.09 |
| | Example 2-8 | Test | | | |
| | | After Bending | 7.35 | 692 | 3.05 |
| | | Test | | | |
| Example 2-21 | Prepared in | No Bending | 7.15 | 703 | 3.02 |
| | Example 2-9 | Test | | | |
| | | After Bending | 7.05 | 702 | 2.97 |
| | | Test | | | |
| Comparative | Prepared in | No Bending | 7.65 | 710 | 3.26 |
| Example 2-1 | Comparative | Test | | | |
| | Example 2-1 | After Bending | | | |
| | | Test | | | |

Table 1 shows that the dye-sensitized solar cells according to Examples 2-13 to 2-21 each have good current-voltage characteristics, no matter whether the electrically-conductive substrate is subjected to the bending test.

1. A method of producing a substrate for a dye-sensitized solar cell, comprising the processes of:
applying, to a heat-resistant substrate, an intermediate layer-forming coating material that contains an organic material and fine particles of a metal oxide semiconductor and setting the coating to form an intermediate layer-forming layer;
applying, to the intermediate layer-forming layer, an oxide semiconductor layer-forming coating material whose solids have a higher concentration of fine particles of a metal oxide semiconductor than the concentration of the fine particles of the metal oxide semiconductor in the solids of the intermediate layer-forming coating material and setting the coating to form an oxide semiconductor layer-forming layer;
sintering the intermediate layer-forming layer and the oxide semiconductor layer-forming layer to form a porous intermediate membrane and a porous oxide semiconductor membrane; and
forming a first electrode layer and a substrate on the oxide semiconductor membrane.

2. The method according to claim 1, wherein the process of forming the electrode and the substrate includes:
the process of a solution treatment in which a first electrode undercoat layer-forming coating material containing a dissolved metal salt or metal complex with a metal element for forming the first electrode layer is brought into contact with the oxide semiconductor membrane so that a first electrode undercoat layer is formed in the interior of or on the surface of the oxide semiconductor membrane; and
the process of forming a first electrode upper layer on the first electrode undercoat layer.

3. The method according to claim 2, wherein the process of forming the first electrode upper layer includes: heating the first electrode undercoat layer to a temperature equal to or higher than a metal oxide film-forming temperature; and bringing the heated first electrode undercoat layer into contact with a first electrode upper layer-forming coating material containing a dissolved metal salt or metal complex with a metal element for forming the first electrode layer to form the first electrode upper layer on the first electrode undercoat layer.

4. The method according to claim 1, wherein the process of forming the electrode and the substrate includes: heating the oxide semiconductor membrane to a temperature equal to or higher than a metal oxide film-forming temperature; and bringing the heated oxide semiconductor membrane into contact with a first electrode layer-forming coating material containing a dissolved metal salt or metal complex with a metal element for forming the first electrode layer to form the first electrode layer on the oxide semiconductor membrane.

5. The method according to any one of claims 1 to 4, wherein the process of forming the electrode and the substrate includes:
providing the substrate, wherein the substrate includes a transparent resin film, an electrically-conductive transparent inorganic layer formed on the resin film, and an electrically-conductive transparent organic-inorganic composite layer formed on the inorganic layer; and bonding the electrically-conductive transparent organic-inorganic composite layer to the first electrode layer.

6. A method of producing a dye-sensitized solar cell, comprising the processes of:
forming a dye-sensitized solar cell substrate by using the method according to any one of claims 1 to 5;
placing a second electrode layer and a counter substrate opposite to the first electrode layer and the substrate of the dye-sensitized solar cell substrate; and
forming an electrolyte layer between the second electrode layer and a photoelectric conversion layer having at least an intermediate layer and an oxide semiconductor layer which includes the porous intermediate membrane, the porous oxide semiconductor membrane and a dye sensitizer fixed on the surface of fine semiconductor particles of the porous intermediate membrane and the porous oxide semiconductor membrane.

7. A substrate for a dye-sensitized solar cell, comprising: a substrate; a first electrode layer formed on the substrate; and an oxide semiconductor layer formed on the first electrode layer, wherein
a metal element used as a component of the first electrode layer is detected in the oxide semiconductor layer, and the concentration of the metal element in the oxide semiconductor layer decreases in the direction from first electrode layer-side surface to opposite surface.

8. A dye-sensitized solar cell, comprising:
a dye-sensitized solar cell substrate which includes a substrate, a first electrode layer formed on the substrate, and an oxide semiconductor layer formed on the first electrode layer;
a counter electrode substrate which includes a counter substrate and a second electrode layer formed on the counter substrate, wherein the second electrode layer is placed opposite to the oxide semiconductor layer; and
an electrolyte layer placed between the oxide semiconductor layer and the second electrode layer, wherein
a metal element used as a component of the first electrode layer is detected in the oxide semiconductor layer, and the concentration of the metal element in the oxide semiconductor layer decreases in the direction from first electrode layer-side surface to opposite surface.

9. An electrically-conductive substrate, comprising: a transparent resin film; and an electrically-conductive transparent inorganic layer, an electrically-conductive transparent organic-inorganic composite layer, a first electrode layer, and an oxide semiconductor layer stacked on the transparent resin film in this order.

10. An electrode substrate for a dye-sensitized solar cell, comprising: the electrically-conductive substrate according to claim 9; and a sensitizing dye fixed on the oxide semiconductor layer of the electrically-conductive substrate.

11. A dye-sensitized solar cell, comprising: a dye-sensitized solar cell substrate having an oxide semiconductor layer on which a sensitizing dye is fixed; a counter electrode substrate placed opposite to the dye-sensitized solar cell substrate; and an electrolyte layer placed between the dye-sensitized solar cell substrate and the counter electrode substrate, wherein
the dye-sensitized solar cell substrate is the electrode substrate according to claim 10.

12. A transfer member for use in forming a semiconductor layer, comprising: a heat-resistant substrate; and an oxide semiconductor layer consisting of a large number of fine particles of an oxide semiconductor and a first electrode layer which are formed on the heat-resistant substrate in this order, wherein
when the first electrode layer formed on the heat-resistant substrate is bonded to any other member, and then the heat resistant substrate is peeled off, peeling occurs at a predetermined peeling interface so that the oxide semiconductor layer can uniformly be placed on the any other member via the first electrode layer.
